(19) United States
(12) Patent Application Publication
(10) Pub. No.: US 2006/0125024 A1
(43) Pub. Date: Jun. 15, 2006

(54) Semiconductor device and a method of manufacturing the same

(76) Inventor: Yoshiyuki Ishigaki, Hitachinaka (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/297,501

(22) Filed: Dec. 9, 2005

(30) Foreign Application Priority Data
Dec. 9, 2004 (JP) 2004-356216

(51) Int. Cl. H01L 21/8234; H01L 29/76

(52) U.S. Cl. 257/390; 438/275; 438/424

(57) ABSTRACT

To improve reliability of FETs having element isolation regions for electrically isolating field effect transistors adjacent to each other in the gate length direction in a mask ROM region, the isolation regions are each constructed by field plate isolation formed simultaneously with gate electrodes of the field effect transistors. This relatively lessens a stress generated in an active region ACT sandwiched by the element isolation regions even if the isolation width of each element isolation region is made relatively small, specifically, less than 0.3 μm. It is therefore possible to relax or prevent the generation of crystal defects resulting from the stress, thereby reducing occurrence of an undesired leak current between the source and drain of each field effect transistor.

### CROSS-REFERENCE TO RELATED APPLICATION

The present application claims priority from Japanese patent application No. 2004-356216 filed on Dec. 09, 2004, the content of which is hereby incorporated by reference into this application.

### BACKGROUND OF THE INVENTION

The present invention relates to a semiconductor device and a manufacturing method of the same, in particular, to a technology effective when applied to the manufacture of a plurality of field effect transistors electrically isolated each other by an element isolation region having a width less than 0.3 μm.

Shallow trench isolation (which will hereinafter be abbreviated as “STI”) is one of element isolation structures enabling electrical isolation of two adjacent semiconductor elements. The STI is a structure obtained by making a trench having, for example, a depth of approximately 0.4 μm in an element isolation region of a substrate and then filling an insulating film therein or has such a structure.

For example, in Japanese Unexamined Patent Publication No. 2003-203989, disclosed is a semiconductor device obtained by, in order to generate a compression stress in the channel portion of p channel field effect transistors, isolating a long active region extending over the plurality of transistors by gate electrodes and arranging a sufficiently thin STI between two gate electrodes.

In Japanese Unexamined Patent Publication No. 2004-200650, disclosed is an electrostatic discharge protection device having a guard ring, which is formed over the surface of a p type substrate to encompass a plurality of NMIS transistors and is composed of a p⁺ type diffusion layer, and an element isolation insulating film formed between the plurality of NMIS transistors and the guard ring.

### OBJECT AND SUMMARY OF THE INVENTION

A flash memory is a type of nonvolatile memory and can electrically write and erase data. It has various technical problems as described below.

The present inventors are now developing a 4 Gbit flash memory having a mask ROM (Read Only Memory) embedded in one chip. Upon development, further miniaturization of a semiconductor element is required. A variety of studies have been made to achieve this, but several problems have still remained undissolved. For example, the minimum width of an element isolation region in a region in which a mask ROM is formed is set to about 0.3 μm in a 1 Gbit flash memory, while it is set to less than 0.3 μm in a 4 Gbit flash memory. It has however become apparent that when the width of the element isolation region is set to less than 0.3 μm, an undesired leak current occurs between the source and drain of field effect transistors constituting the mask ROM and causes problems such as an increase in power consumption or destruction of ROM data.

A plurality of field effect transistors constituting a mask ROM are arranged with an element isolation region having a width less than 0.3 μm sandwiched therebetween. This element isolation region is composed of STI. After formation of the STI, the substrate is subjected to oxidation or heat treatment. This treatment causes volume expansion or shrinkage of an insulating film filled inside of the trench of the STI and generates a stress in an active region (for example, refer to Japanese Unexamined Patent Publication No. 2003-203989). It is presumed that as a result, the stress triggers formation of crystal defects in the active region and causes the above-described leak current.

An object of the present invention is to provide a technology capable of improving the reliability of field effect transistors electrically isolated by an element isolation region having a width less than 0.3 μm.

The above-described and the other objects and novel features of the present invention will be apparent by the description herein and accompanying drawings.

Outline of the typical inventions, among those disclosed by this application, will next be described briefly.

A semiconductor device according to the present invention has a mask ROM region formed over the main surface of a semiconductor substrate and equipped with a plurality of field effect transistors, a plurality of active regions in which the field effect transistors are formed respectively, and element isolation regions for electrically isolating the active regions adjacent to each other, wherein the element isolation regions located in a gate length direction of the field effect transistors and a direction vertical thereto are each composed of field plate isolation.

A manufacturing method of a semiconductor device according to the present invention comprises the steps of: forming, in a mask ROM region over the main surface of a semiconductor substrate, shallow trench isolation extending in a first direction to form an active region encompassed by the shallow trench isolation; and forming a gate insulating film over the surface of the active region of the semiconductor substrate, and simultaneously forming a first gate electrode of a plurality of field effect transistors extending in the first direction and a second direction vertical thereto over the gate insulating film and a second gate electrode of field plate isolation extending in the second direction in a region electrically isolating the field effect transistors arranged contiguous to each other in the first direction.

Advantages available by the typical inventions, of the inventions disclosed by the present application, will next be described briefly.

In a semiconductor device having an element isolation region, reliability of a field effect transistor can be improved by reducing the inconvenience, that is, flow of a leak current resulting from crystal defects, for example, an undesired leak current between the source and drain of the field effect transistor.

### BRIEF DESCRIPTION OF THE DRAWINGS

FIGS. 1(a) and 1(b) are fragmentary plan views of an NOR type flash memory according to Embodiment 1 of the present invention during its manufacturing step, in which FIG. 1(a) is a fragmentary plan view of a mask ROM region and FIG. 1(b) is a fragmentary plan view of a peripheral circuit region other than the mask ROM region;

FIG. 2 is a fragmentary cross-sectional view of the flash memory during a similar manufacturing step to that of FIG. 1;

FIG. 3 is a fragmentary cross-sectional view of a similar portion of the flash memory to that of FIG. 2 during a manufacturing step following that of FIG. 1 and FIG. 2;

FIG. 4 is a fragmentary cross-sectional view of a similar portion of the flash memory to that of FIG. 2 during a manufacturing step following that of FIG. 3;

FIG. 5 is a fragmentary plan view of a similar portion of the flash memory to that of FIG. 1 during a manufacturing step following that of FIG. 4;

FIG. 6 is a fragmentary cross-sectional view of a similar portion of the flash memory to that of FIG. 2 during a manufacturing step following that of FIG. 4;

FIG. 7 is a fragmentary cross-sectional view of a similar portion of the flash memory to that of FIG. 2 during a manufacturing step following that of FIG. 5 and FIG. 6;

FIG. 8 is a fragmentary cross-sectional view of a similar portion of the flash memory to that of FIG. 2 during a manufacturing step following that of FIG. 7;

FIG. 9 is a fragmentary plan view of a similar portion of the flash memory to that of FIG. 1 during a manufacturing step following that of FIG. 8;

FIG. 10 is a fragmentary cross-sectional view of a similar portion of the flash memory to that of FIG. 2 during a manufacturing step following that of FIG. 8;

FIG. 11 is a fragmentary plan view of a similar portion of the flash memory to that of FIG. 1 during a manufacturing step following that of FIG. 9 and FIG. 10;

FIG. 12 is a fragmentary cross-sectional view of a similar portion of the flash memory to that of FIG. 2 during a manufacturing step following that of FIG. 9 and FIG. 10;

FIG. 13 is a fragmentary plan view of a similar portion of the flash memory to that of FIG. 1 during a manufacturing step following that of FIG. 11 and FIG. 12;

FIG. 14 is a fragmentary cross-sectional view of a similar portion of the flash memory to that of FIG. 2 during a manufacturing step following that of FIG. 11 and FIG. 12;

FIGS. 15(a) and 15(b) are fragmentary plan views of an AND flash memory according to Embodiment 2 of the present invention during its manufacturing step, in which FIG. 15(a) is a fragmentary plan view of a mask ROM region and FIG. 15(b) is a fragmentary plan view of a peripheral circuit region other than the mask ROM region;

FIG. 16 is a fragmentary cross-sectional view of the flash memory during a similar manufacturing step to that of FIG. 15;

FIG. 17 is a fragmentary plan view of a similar portion of the flash memory to that of FIG. 15 during a manufacturing step following that of FIG. 15 and FIG. 16;

FIG. 18 is a fragmentary cross-sectional view of a similar portion of the flash memory to that of FIG. 16 during a manufacturing step following that of FIG. 15 and FIG. 16;

FIG. 19 is a fragmentary cross-sectional view of a similar portion of the flash memory to that of FIG. 16 during a manufacturing step following that of FIG. 17 and FIG. 18;

FIG. 20 is a fragmentary cross-sectional view of a similar portion of the flash memory to that of FIG. 16 during a manufacturing step following that of FIG. 19;

FIG. 21 is a fragmentary plan view of a similar portion of the flash memory to that of FIG. 15 during a manufacturing step following that of FIG. 20;

FIG. 22 is a fragmentary cross-sectional view of a similar portion of the flash memory to that of FIG. 16 during a manufacturing step following that of FIG. 20;

FIG. 23 is a fragmentary cross-sectional view of a similar portion of the flash memory to that of FIG. 16 during a manufacturing step following that of FIG. 21 and FIG. 22;

FIG. 24 is a fragmentary plan view of a similar portion of the flash memory to that of FIG. 15 during a manufacturing step following that of FIG. 23;

FIG. 25 is a fragmentary cross-sectional view of a similar portion of the flash memory to that of FIG. 16 during a manufacturing step following that of FIG. 23;

FIG. 26 is a fragmentary plan view of a similar portion of the flash memory to that of FIG. 15 during a manufacturing step following that of FIG. 24 and FIG. 25;

FIG. 27 is a fragmentary cross-sectional view of a similar portion of the flash memory to that of FIG. 16 during a manufacturing step following that of FIG. 24 and FIG. 25;

FIG. 28 is a fragmentary plan view of a similar portion of the flash memory to that of FIG. 15 during a manufacturing step following that of FIG. 26 and FIG. 27;

FIG. 29 is a fragmentary cross-sectional view of a similar portion of the flash memory to that of FIG. 16 during a manufacturing step following that of FIG. 26 and FIG. 27;

FIGS. 30(a) and 30(b) are fragmentary plan views of an AND flash memory according to Embodiment 3 of the present invention during its manufacturing step, in which FIG. 30(a) is a fragmentary plan view of a mask ROM region and FIG. 30(b) is a fragmentary plan view of a peripheral circuit region other than the mask ROM region;

FIG. 31 is a fragmentary cross-sectional view of the flash memory during a similar manufacturing step to that of FIG. 30;

FIG. 32 is a fragmentary cross-sectional view of a similar portion of the flash memory to that of FIG. 31 during a manufacturing step following that of FIG. 30 and FIG. 31;

FIG. 33 is a fragmentary cross-sectional view of a similar portion of the flash memory to that of FIG. 31 during a manufacturing step following that of FIG. 32;

FIG. 34 is a fragmentary cross-sectional view of a similar portion of the flash memory to that of FIG. 31 during a manufacturing step following that of FIG. 33;

FIG. 35 is a fragmentary cross-sectional view of a similar portion of the flash memory to that of FIG. 31 during a manufacturing step following that of FIG. 34;

FIG. 36 is a fragmentary cross-sectional view of a similar portion of the flash memory to that of FIG. 31 during a manufacturing step following that of FIG. 35;

FIG. 37 is a fragmentary plan view of a similar portion of the flash memory to that of FIG. 30 during a manufacturing step following that of FIG. 36;

FIG. 38 is a fragmentary cross-sectional view of a similar portion of the flash memory to that of FIG. 31 during a manufacturing step following that of FIG. 36; and

FIG. 39 is a chip block diagram illustrating a main circuit block inside of a semiconductor chip of a semiconductor device having, mounted thereover, the flash memory according to the embodiment of the present invention.

### DESCRIPTION OF THE PREFERRED EMBODIMENTS

In the below-described embodiments, a description will be made after dividing it into plural sections or into plural embodiments if necessary for convenience's sake. These plural sections or embodiments are not independent of each other, but in a relation such that one is a modification example, details or complementary description of a part or whole of the other one unless otherwise specifically indicated.

In the below-described embodiments, when a reference is made to a number of elements (including number, value, amount and range), the number is not limited to a specific number but can be greater than or less than the specific number unless otherwise specifically indicated or principally apparent that the number is limited to the specific number. Moreover, in the below-described embodiments, it is needless to say that the constituting elements (including element steps) are not always essential unless otherwise specifically indicated or principally apparent that they are essential. Similarly, in the below-described embodiments, when a reference is made to the shape or positional relationship of the constituting elements, that substantially analogous or similar to it is also embraced unless otherwise specifically indicated or principally apparent that it is not. This also applies to the above-described value and range.

In the drawings used in the embodiments, a plan view is sometimes hatched to facilitate understanding of the drawing. In these embodiments, MIS-FET (Metal Insulator Semiconductor Field Effect Transistor) which is a typical example of a field effect transistor is abbreviated as MIS and a p channel MIS-FET and an n channel MIS·FET are abbreviated as pMIS and nMIS, respectively.

In all the drawings for describing the embodiments, like members of a function will be identified by like reference numerals and overlapping descriptions will be omitted. The embodiments of the present invention will next be described in detail based on accompanying drawings.

### EMBODIMENT 1

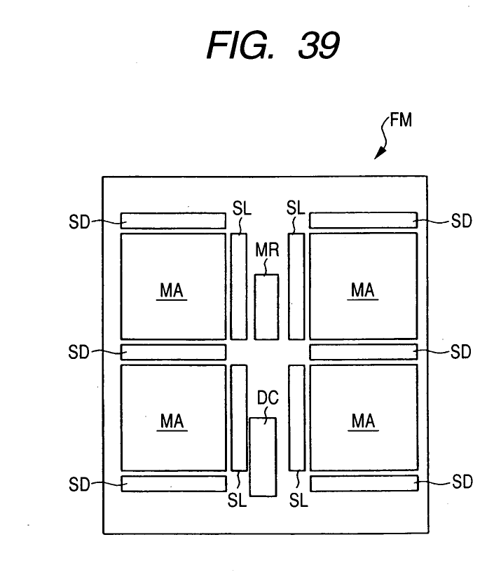

FIG. 39 is a chip block diagram showing a main circuit block inside of a semiconductor chip of a semiconductor device having, mounted thereover, a flash memory according to Embodiment 1.

A semiconductor device FM includes a memory array MA of a flash memory disposed over more than half of the main surface of a semiconductor substrate, a decoder SD for selecting a memory cell, a sense amplifier data latch SL for amplifying a feeble signal and storing data, and a logic portion for controlling this circuit portion. It further includes a mask ROM region MR and a power source DC. The memory array MA has a predetermined number of word lines WL disposed at a predetermined pitch, a predetermined number of bit lines disposed at a predetermined pitch in a direction vertical to the word lines, and many memory cells arranged in a lattice shape at substantial intersections between the word lines and the bit lines.

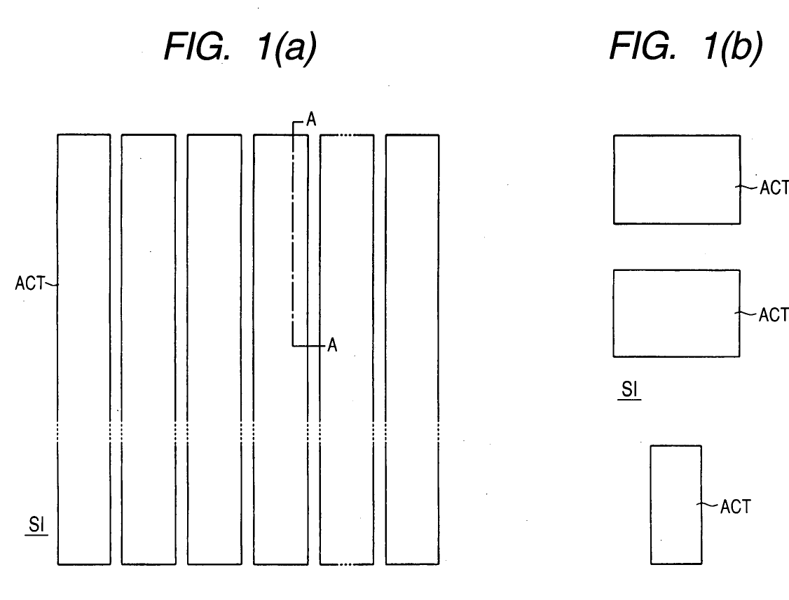

One example of manufacturing methods of the flash memory according to Embodiment 1 will be described in the order of steps based on FIGS. 1 to 14. In this example, the present invention is applied to a manufacturing method of an NOR flash memory.

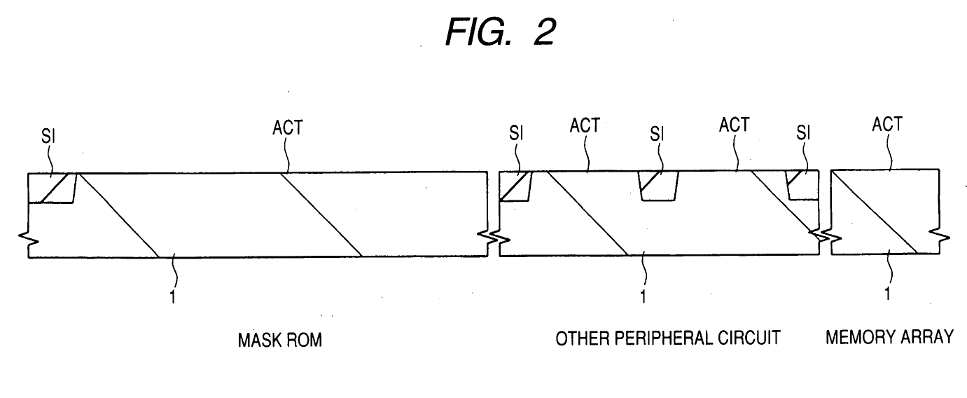

FIGS. 1 and 2 illustrate the flash memory according to Embodiment 1 during its manufacturing step. FIG. 1(a) is a fragmentary plan view of a mask ROM region, for example, a mask ROM region MR of FIG. 39, while FIG. 1(b) is a fragmentary plan view of a peripheral circuit region (which will hereinafter be called “other peripheral circuit region) other than the mask ROM region, for example, a fragmentary plan view of semiconductor elements constituting the decoder SD, sense amplifier data latch SL, logic portion and power source DC. FIG. 2 is a fragmentary cross-sectional view including the mask ROM region, other peripheral circuit region and memory array and in the mask ROM region, a fragmentary cross-sectional view taken along a line A-A of FIG. 1(a) is illustrated.

An isolation portion SI, for example, in the form of a trench and an active region ACT encompassed thereby are formed in the main surface of a semiconductor substrate (at this stage, a so-called semiconductor wafer which is a thin semiconductor plate in the flat and substantially round form) 1 made of, for example, single crystal silicon. The isolation portion SI is formed in an element isolation region having a width of 0.3 μm or greater (which region will hereinafter be called “first element isolation region”) and is not formed in an element isolation region having a width of less than 0.3 μm (which region will hereinafter be called “second element isolation region”). The first element isolation region is a region used for, for example, isolation of nMISs adjacent to each other in a gate width direction of a local word line among nMISs formed in the mask ROM region, isolation of nMIS and pMIS formed in the other peripheral circuit region, and element isolation of a memory array. The second element isolation region is, for example, a region used for isolation of nMISs adjacent to each other in the gate length direction of the local word line among nMISs formed in the mask ROM region. In short, the second element isolation region is a region formed in a portion of the active region ACT of the mask ROM region. In Embodiment 1, therefore, as described later in detail, an isolation gate electrode for field plate isolation (which will hereinafter be called “isolation MIS”) is formed only in a region for electrically isolating nMISs adjacent to each other in the gate length direction of the local word line in the mask ROM region.

In Embodiment 1, an example in which isolation MISs are formed in the second element isolation region in the order of isolation MIS, nMIS, nMIS, isolation MIS, n MIS . . . in the gate length direction is shown.

The isolation portion SI will be formed, for example, in the following manner. A semiconductor substrate 1 is heat treated at about 850° C. in an oxidizing atmosphere to form a pad oxide film of about 10 nm thick over the main surface of the substrate.

A silicon nitride film of about 120 nm thick is deposited over the resulting pad oxide film by CVD (Chemical Vapor Deposition). With a resist pattern formed by photolithography as a mask, the silicon nitride film and the pad oxide film exposed therefrom are removed from the first element isolation region by dry etching. The pad oxide film is formed in order to relax a stress which will be applied to the semiconductor substrate 1 when a silicon oxide film to be filled in an isolating trench is densified in the later step. The silicon nitride film is resistant to oxidation so that it is used as a mask for preventing oxidation of the surface of the semiconductor substrate 1 below (active region ACT) the silicon nitride film.

With the silicon nitride film as a mask, the semiconductor substrate 1 exposed therefrom is removed by dry etching to form an isolation trench of about 350 nm deep in the semiconductor substrate 1 of the first element isolation region. Then, in order to remove a damage layer formed over the inside wall of the isolation trench by etching, the semiconductor substrate 1 is heat treated in an oxidizing atmosphere at about 1000° C. to form a silicon oxide film of about 10 nm thick over the inside wall of the isolation trench. At this time, by further heat treatment in an atmosphere containing oxygen and nitrogen, an oxynitride silicon film can be formed over the inside wall of the isolation trench. In this case, a stress which will be applied to the semiconductor substrate 1 when a silicon oxide film to be filled inside of the isolation trench is densified in the later step can be relaxed further. In stead of the above-described heat treatment in an atmosphere containing oxygen and nitrogen, a silicon nitride film may be formed by CVD. Similar effects are available by this method.

An insulating film made of, for example, silicon oxide is then deposited over the main surface of the semiconductor substrate 1 by CVD and in order to improve the quality of the insulating film, it is dehsified by heat treatment of the semiconductor substrate 1. By CMP (chemical mechanical polishing) using the silicon nitride film as a stopper, the insulating film is polished to leave it inside of the isolation trench, whereby an isolation portion SI having a planarized surface is formed.

The insulating film left inside of the isolation trench is not limited to a silicon oxide film formed by CVD and instead, a silicon oxide film formed by the application method can also be employed. Compared with a silicon oxide film formed by CVD, that formed by the application method has improved burying properties in the isolation trench. Similar effect is available even if the lower portion in the isolation trench is filled with a silicon oxide film formed by the application method and then the remaining upper portion is filled with a silicon oxide film formed by CVD, in other words, a film stack of a silicon oxide film formed by the application method and a silicon oxide film formed by CVD is filled in the trench.

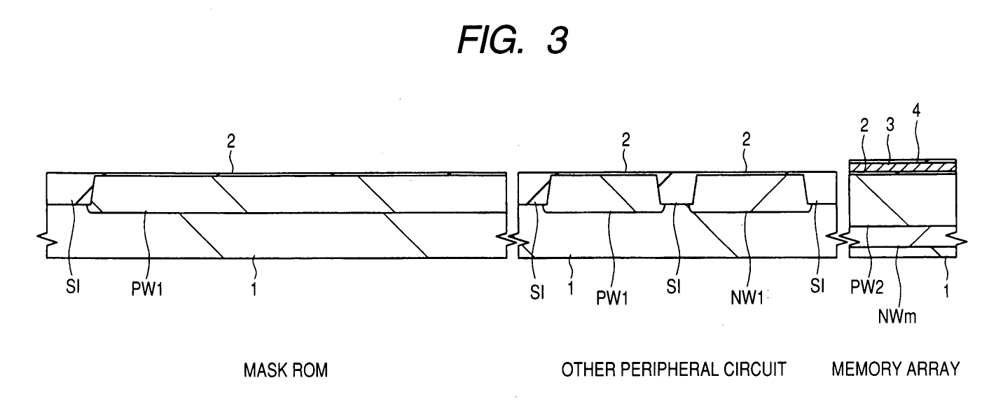

FIG. 3 is a fragmentary cross-sectional view of a similar portion to that of FIG. 2 in a manufacturing step following that of FIGS. 1 and 2.

A buried n well NWm, p wells PW1 and PW2, and an n well NW1 are each formed by introducing a predetermined impurity in a predetermined portion of the semiconductor substrate 1 at a predetermined energy by using selective ion implantation method. For example, boron (B) ions are implanted into the p well PW1 in the mask ROM region at a dose of approximately 5×10¹² to 1×10¹³ cm⁻². In addition to this ion implantation, with a resist pattern formed by photolithography as a mask, for example, boron ions may be implanted into the p well PW1 of the second element isolation region exposed from the mask at a dose of approximately 5×10¹² to 1×10¹³ cm⁻². The threshold voltage of the isolation MIS, which will be described later, can be set higher by the introduction of this impurity.

A tunnel insulating film of the memory cell is then formed over the main surface of the semiconductor substrate 1. After formation of an insulating film 2, for example, about 10 nm thick by thermal oxidation, a conductor film made of low resistance polycrystalline silicon about 100 nm thick is deposited over the main surface of the semiconductor substrate 1. During the formation of the insulating film 2, end portions of the isolation trench of the isolation portion SI are oxidized so that a stress is applied onto the interface between the silicon (silicon constituting the semiconductor substrate 1) at end portions and the silicon oxide film (the silicon oxide film filled inside of the isolation trench). However, the first element isolation region has a width of 0.3 μm or greater and is relatively wide so that a stress caused by the isolation region SI in the active region ACT is relatively small. With a resist pattern formed by photolithography as a mask, the conductor film exposed therefrom is removed by dry etching, whereby a floating gate electrode 3 of the memory cell is patterned in the gate width direction.

An interlayer film 4 of about 18 nm thick is then formed by successively depositing, for example, a silicon oxide film, a silicon nitride film and a silicon oxide film over the main surface of the semiconductor substrate 1 by CVD. With a resist pattern formed by photolithography as a mask, the interlayer film 4 and conductor film are removed from the mask ROM region and other peripheral circuit region by dry etching.

A problem which must be considered in the manufacture of a semiconductor device having a flash memory is an increase in the number of steps of depositing a silicon oxide film or silicon nitride film as in the formation of such an interlayer film 4. The formation of an interlayer film 4 is accompanied with an increase in the heat treatment frequency or a mixed amount of an oxygen gas, which may cause a change in the volume of the insulating film filled inside of the isolation trench of the isolation portion SI and increase a stress onto the active region ACT. In short, manufacture of a semiconductor device having a flash memory involves the problem that a stress tends to occur, which may lead to the formation of crystal defects.

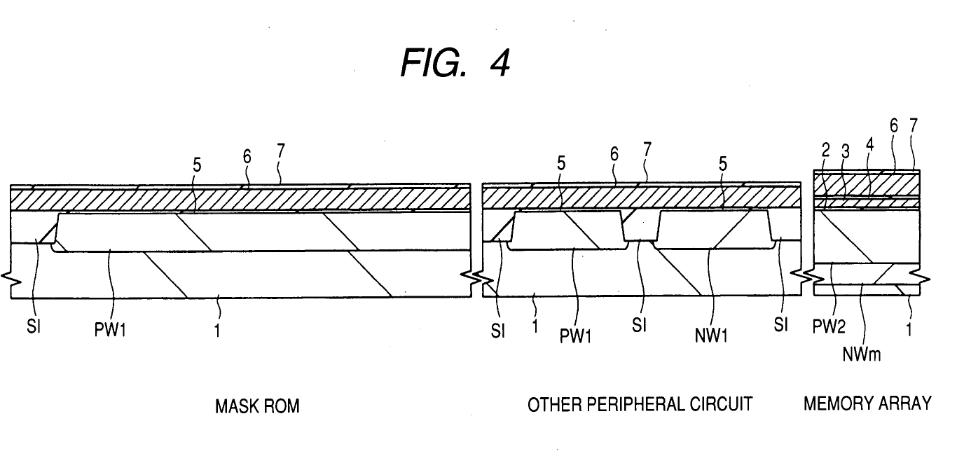

FIG. 4 is a fragmentary cross-sectional view of a similar portion to that of FIG. 2 in a manufacturing step following that of FIG. 3.

A gate insulating film 5 of about 10 nm thick is formed over the main surface of the semiconductor substrate 1 in the mask ROM region and other peripheral circuit region, for example, by thermal oxidation. When the gate insulating film 5 is formed, end portions of the isolation trench of the isolation portion SI are also oxidized similar to that during formation of the insulating film 2 so that a stress is applied onto the interface between silicon at the end portions and the silicon oxide film. The stress generated in the active region ACT by the isolation portion SI is, however, small enough to be neglected, because the first element isolation region has a width of 0.3μpm or greater and is relatively wide. A conductor film 6 about 70-nm thick made of low resistance polycrystalline silicon and a cap insulating film 7 composed of silicon oxide are deposited successively over the main surface of the semiconductor substrate 1 by CVD.

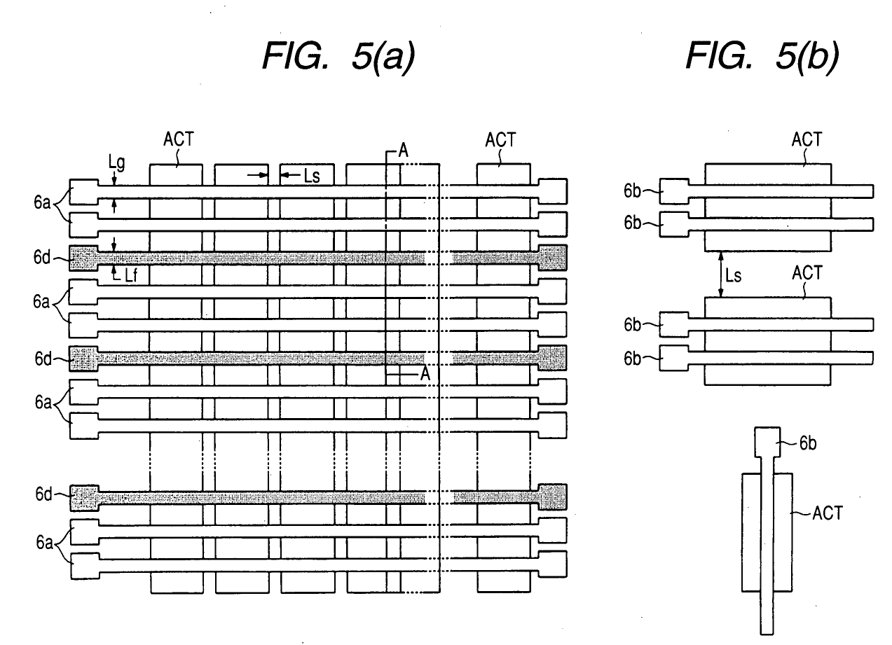

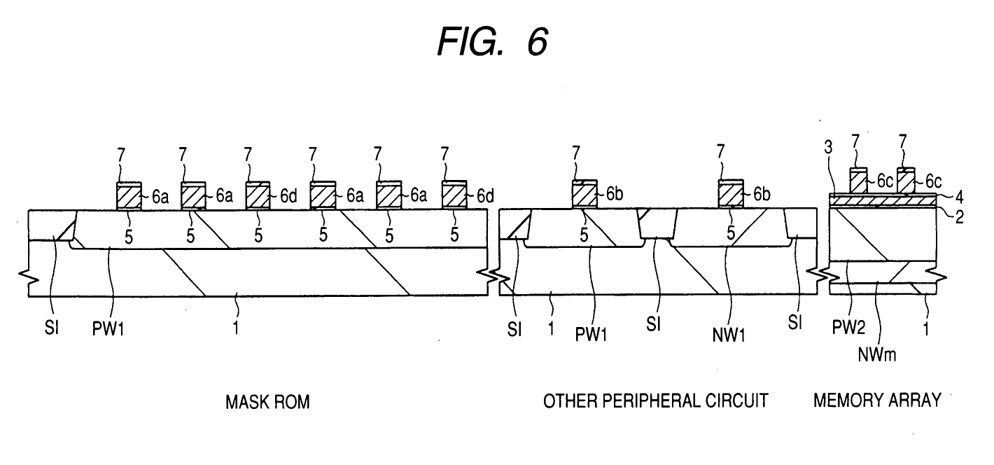

FIG. 5(a) is a fragmentary plan view of a similar portion to that of FIG. 1(a) in a manufacturing step following that of FIG. 4, FIG. 5(b) is a fragmentary plan view of a similar portion to that of FIG. 1(b) in this step and FIG. 6 is a fragmentary cross-sectional view of a similar portion to that of FIG. 2 in this step.

With a resist pattern formed by photolithography as a mask, the cap insulating film 7 and conductor film 6 exposed therefrom are removed by dry etching to form a gate electrode (local word line) 6a of the nMIS in the mask ROM region, gate electrode 6b of each of the nMIS and pMIS in the other peripheral circuit region, and a control gate electrode (word line) 6c of the memory cell in the memory array. At the same time, an isolation gate electrode 6d of an isolation MIS is formed in the second element isolation region of the mask ROM region. Each of the gate electrodes 6a, 6b, 6c and 6d may be formed by patterning the cap insulating film 7 and conductor film 6 successively with the resist pattern as a mask, or patterning the cap insulating film 7 with the resist pattern as a mask and then patterning the conductor film 6 with this cap insulating film 7 as a mask.

The isolation gate electrode 6d of the isolation MIS is formed in the second element isolation region for electrically isolating, among a plurality of nMISs formed in the mask ROM region, the nMISs disposed in the gate length direction of the gate electrode 6a. The nMISs adjacent to each other in the gate length direction of the mask ROM region are electrically isolated by applying GND (0 V) or a negative voltage to the isolation gate electrode 6d of the isolation MIS. A voltage applied to the isolation gate electrode 6d having a gate length less than 0.3 μm is presumed to be appropriate when it falls within a range of from 0 to −2 V (it is needless to say that the voltage is not limited to fall within this range, depending on the conditions). In other words, a voltage applied to the isolation gate electrode 6d is lower than that to be applied to the gate electrode 6a of the nMIS to be used as the mask ROM and its proper range is 0 V or less. As described above, the isolation MIS has properties different from those of the nMIS in the mask ROM region and it does not function as a semiconductor element.

The nMISs adjacent to each other in the gate length direction of the mask ROM region may be electrically isolated by introducing an impurity into the channel region of the isolation MIS in advance and setting the threshold voltage of the isolation MIS higher than that of the nMIS in the mask ROM region. In either case, a gate length Lf of the isolation gate electrode 6d of the isolation MIS can be made equal or less than a gate length Lg of the gate electrode 6a of the nMIS in the mask ROM region and moreover, shorter than a width Ls of the isolation portion SI formed in the first element isolation region. For example, it is possible to adjust the gate length Lg of the gate electrode 6a of the nMIS in the mask ROM region to fall within a range of 0.3 μm or greater but not greater than 0.5 μm and the gate length Lf of the isolation gate electrode 6d of the isolation MIS to fall within a range of 0.1 μm or greater but less than 0.3 μm.

In the case where the isolation portion SI having STI is formed in the second element isolation region for electrically isolating the active region ACT in the gate length direction of the nMIS formed in the mask ROM region, crystal defects penetrating between the source and drain of the nMIS formed in the mask ROM region tends to occur by the stress. By forming the isolation MIS in the second element isolation region, however, generation of the crystal defects can be relaxed or prevented.

In such a manner, element isolation made of the isolation MIS can be formed in the second element isolation region for isolating nMISs adjacent to each other in the gate length direction of the mask ROM region and having a relatively narrow isolation width less than 0.3 pum. By forming the isolation MIS in the second element isolation region in the mask ROM region, a stress generated in the active region ACT which is sandwiched between the second element isolation regions and in which source and drain of the nMIS are formed can be reduced, whereby generation of crystal defects owing to stress can therefore be relaxed or prevented. In other words, compared with the related art by which an isolation portion SI is formed by making an isolation trench in the second element isolation region and depositing an insulating film inside of the isolation trench, a stress generated in the active region ACT can be reduced.

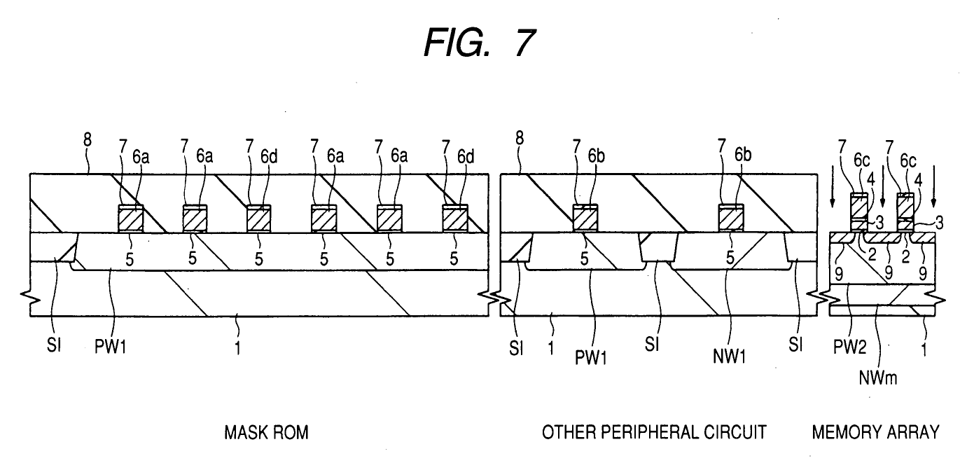

FIG. 7 is a fragmentary cross-sectional view of a similar portion to that of FIG. 2 in a manufacturing step following that of FIGS. 5 and 6.

A resist pattern 8 is formed by photolithography. With the resist pattern 8 and cap insulating film 7 as a mask, the interlayer film 4 and conductor film exposed therefrom are removed by dry etching, whereby a floating gate electrode 3 of the memory cell is patterned in the gate length direction. By this step, the control gate electrode 6c and floating gate electrode 3 of the memory cell are completed. With the resist pattern 8 as a mask, an impurity for the formation of the source and drain of the memory cell, for example, arsenic (As) or phosphorous (P) is introduced into the semiconductor substrate 1 by ion implantation method to form a pair of n type semiconductor regions 9 constituting a portion of the source and drain.

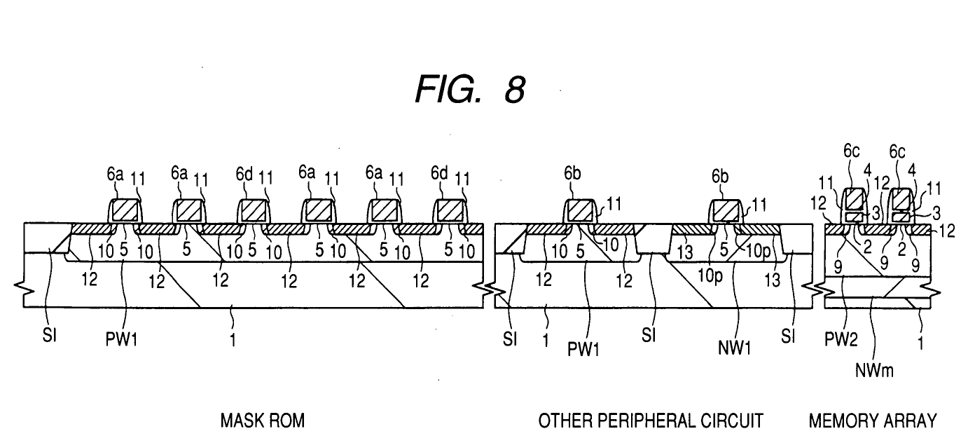

FIG. 8 is a fragmentary cross-sectional view of a similar portion to that of FIG. 2 in a manufacturing step following that of FIG. 7.

A pair of n type semiconductor regions 10 constituting a portion of the source and drain of the nMIS in the mask ROM region and nMIS in the other peripheral circuit region and having a relatively low impurity concentration are formed. Into the n type semiconductor regions 10, arsenic or phosphorous ions are implanted at a dose of approximately 5×10¹² to 1×10¹⁴ cm⁻². A pair of p type semiconductor regions 10p constituting a portion of the source and drain of the pMIS of the other peripheral circuit region and having a relatively low impurity concentration are then formed. Into the p type semiconductor regions 10p, for example, boron or boron fluoride (BF₂) ions are implanted at a dose of approximately 5×10¹² to 1×10¹⁴ cm⁻².

After deposition of an insulating film made of, for example, silicon oxide by CVD over the main surface of the semiconductor substrate 1, the insulating film is etched back by anisotropic dry etching, whereby sidewalls 11 are formed on the side surfaces of the gate electrodes of the memory cell (the floating gate electrode 3 and the control gate electrode 6c) and the gates of various MISs (gate electrode 6a of the nMIS in the mask Rom region, the gate electrodes 6b of the nMIS and pMIS in the other peripheral circuit region, and the isolation gate electrode 6d of the isolation MIS).

A pair of n type semiconductor regions 12 constituting another portion of the source and drain of the nMIS in the mask ROM region, nMIS in the other peripheral circuit region and the memory cell and having a relatively high impurity concentration are formed. Into the n type semiconductor regions 12, arsenic ions are introduced at a level of approximately 1×10²⁰ cm⁻³ or greater. A pair of p type semiconductor regions 13 constituting the source and drain of the pMIS in the other peripheral circuit region and having a relatively high impurity concentration are formed. Into the p type semiconductor regions 13, boron ions are introduced at a level of approximately 1×10²⁰ cm⁻³ or greater.

The semiconductor substrate 1 is then subjected to heat treatment of from about 900 to 1,000° C. in order to activate the impurity ions thus implanted. By this heat treatment, the insulating film 2 is formed and at the same time, the isolation trench of the isolation portion SI is oxidized at the end portions thereof so that a stress is applied onto the interface between silicon at the end portions and the silicon oxide film. The stress generated in the active region ACT by the isolation portion SI is small enough to be neglected, because the first element isolation region has a width of 0.3 μm or greater and is relatively wide. By the above-described steps, the memory cell and various MISs are formed.

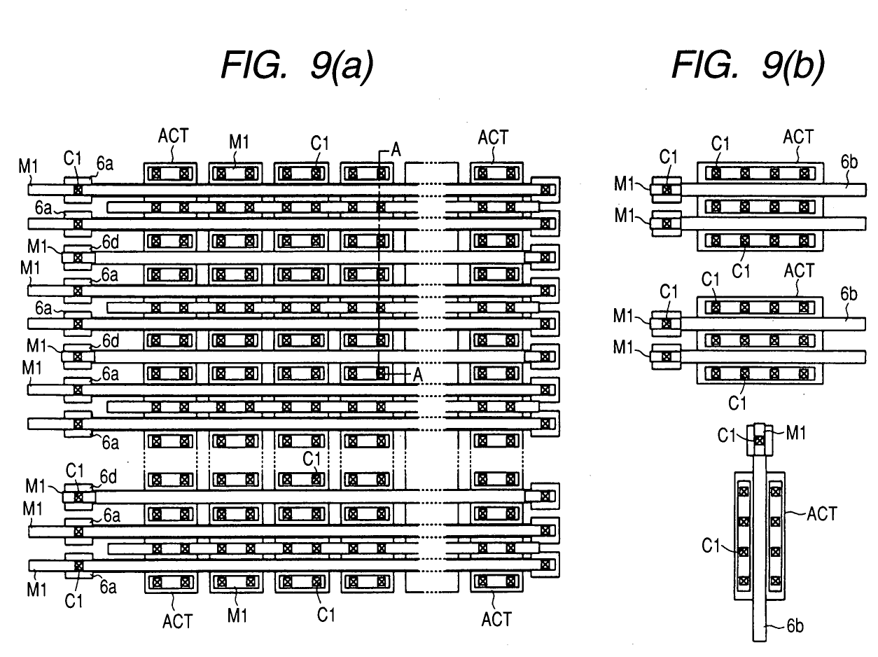

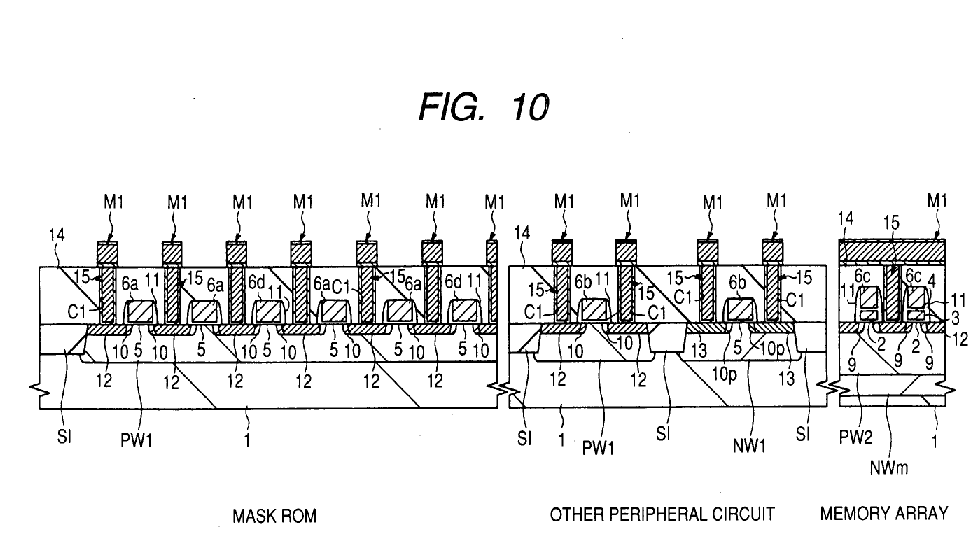

FIG. 9(a) is a fragmentary plan view of a portion similar to that of FIG. 1(a) in a manufacturing step following that of FIG. 8; FIG. 9(b) is a fragmentary plan view of a similar portion to that of FIG. 1(b) in this manufacturing step; and FIG. 10 is a fragmentary cross-sectional view of a similar portion to that of FIG. 2 in this manufacturing step.

An insulating film 14 made of, for example, silicon oxide is formed over the main surface of the semiconductor substrate 1 by CVD. With a resist pattern formed by photolithography as a mask, the insulating film 14 exposed therefrom is removed by dry etching to form contact holes C1 from which portions of the semiconductor substrate (for example, the source and drain of the memory cell and various MISs) and a portion of the word line are exposed.

After a titanium (Ti) film, a titanium nitride (TiN) film and a tungsten (W) film are deposited successively over the main surface of the semiconductor substrate 1 by sputtering or CVD, these metal films are polished by CMP to leave them only inside of each of the contact holes C1, whereby a plug 15 is formed therein. An aluminum (Al) alloy film and a titanium nitride film are deposited successively over the main surface of the semiconductor substrate 1 by sputtering. With a resist pattern formed by photolithography as a mask, the titanium nitride film and aluminum alloy film exposed therefrom are removed by dry etching to form a first-level interconnect M1.

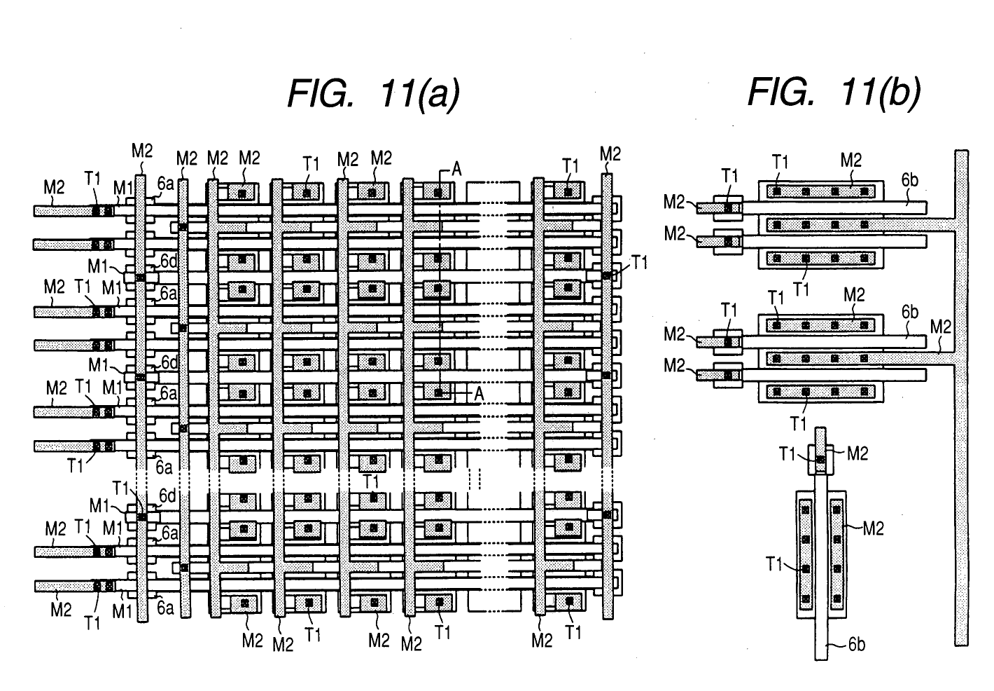

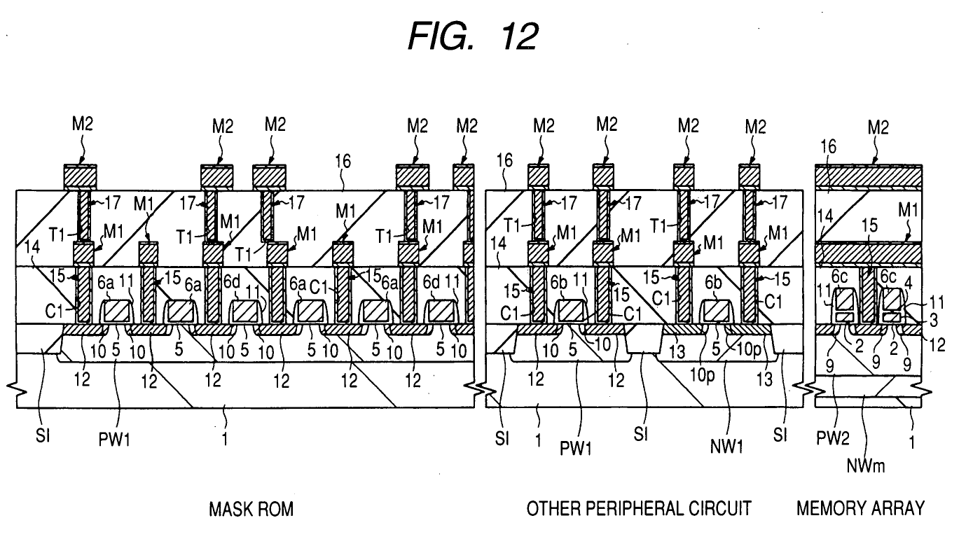

FIG. 11(a) is a fragmentary plan view of a similar portion to that of FIG. 1(a) in the manufacturing step following that of FIGS. 9 and 10; FIG. 11(b) is a fragmentary plan view of a similar portion to that of FIG. 1(b) in this manufacturing step; and FIG. 12 is a fragmentary cross-sectional view of a similar portion to that of FIG. 2 in this manufacturing step.

An insulating film 16 made of, for example, silicon oxide is deposited over the main surface of the semiconductor substrate 1 by CVD. With a resist pattern formed by photolithography as a mask, the insulating film 16 exposed therefrom is removed by dry etching to form, in the insulating film 16, a through-hole T1 from which a portion of the first-level interconnect M1 is exposed.

After successive deposition of a titanium film, a titanium nitride film and a tungsten film over the main surface of the semiconductor substrate 1 by sputtering or CVD, these metal films are polished by CMP to leave them only in the through-hole T1, whereby a plug 17 is formed inside of the through-hole T1. An aluminum alloy film and a titanium nitride film are deposited successively over the main surface of the semiconductor substrate 1 by sputtering. With a resist pattern formed by photolithography as a mask, the titanium nitride film and aluminum alloy film exposed therefrom are removed by dry etching to form a second-level interconnect M2 is formed. This second-level interconnect M2 is electrically connected to the first-level interconnect M1 through the plug 17.

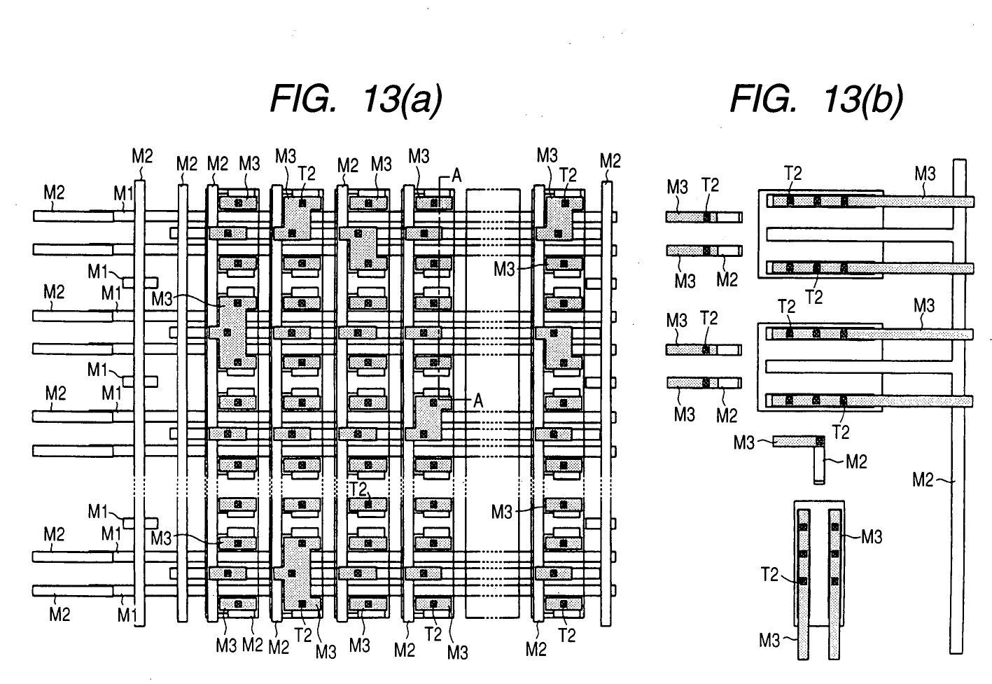

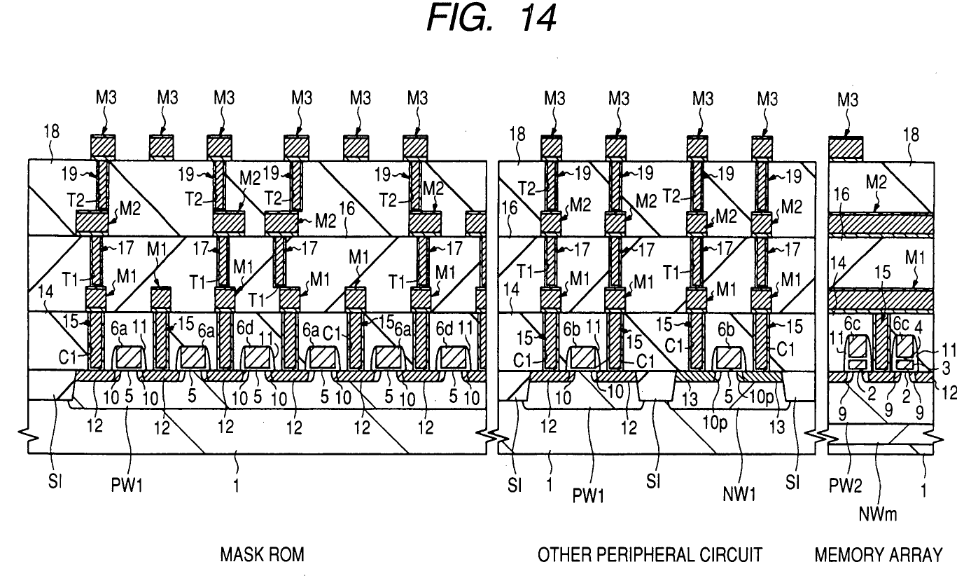

FIG. 13(a) is a fragmentary plan view of a similar portion to that of FIG. 1(a) in a manufacturing step following that of FIGS. 11 and 12; FIG. 13(b) is a fragmentary plan view of a similar portion to that of FIG. 1(b) in this manufacturing step; and FIG. 14 is a fragmentary cross-sectional view of a similar portion to that of FIG. 2 in this manufacturing step.

After deposition of an insulating film 18 made of silicon oxide over the main surface of the semiconductor substrate 1 by CVD, a through-hole T2 from which a portion of the second-level interconnect M2 is exposed is formed in the insulating film 18 in a similar manner to that employed for the through-hole T1. A plug 19 is then formed inside of the through-hole T2 in a similar manner to that employed for the formation of the plug 17 and the second-level interconnect M2 and a third-level interconnect M3 electrically connected to the second-level interconnect M2 is formed via the plug 19.

After upper level interconnects are formed and the uppermost interconnect is covered, at the surface thereof, with a surface protection film, an opening from which a portion of the uppermost interconnect is exposed is formed in a portion of the surface protection film, whereby a bonding pad is formed. In such a manner, the flash memory is manufactured.

As described above, since an isolation MIS can be formed in a second element isolation region for isolating nMISs adjacent to each other in the gate length direction in the mask ROM region and a stress generated in the active region ACT sandwiched between the second element isolation regions can be reduced relatively according to Embodiment 1, generation of crystal defects owing to stress can be reduced or prevented. As a result, even if nMISs formed in the mask ROM region are isolated by the relatively narrow second element isolation region having a width of, for example, less than 0.3 μm, a leak current flowing between the source and drain formed in the active region ACT and resulting from the crystal defects can be reduced, leading to improvement in the reliability of the nMIS formed in the mask ROM region.

### EMBODIMENT 2

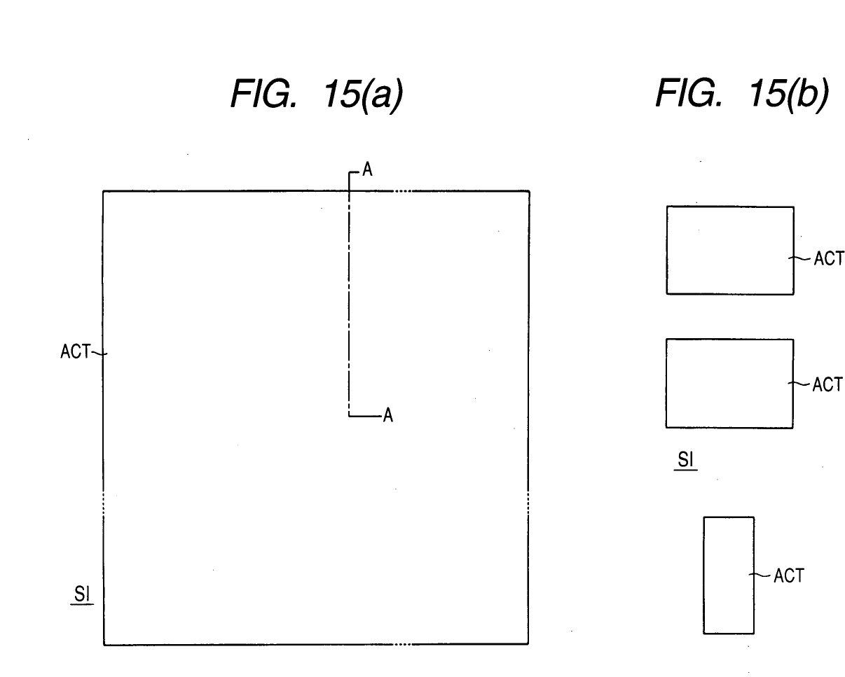

A manufacturing method of a flash memory according to Embodiment 2 will hereinafter be described in the order of steps based on FIGS. 15 to 29. Here, one application example of the present invention to a manufacturing method of an AND type flash memory having an assist gate (AG) will be described.

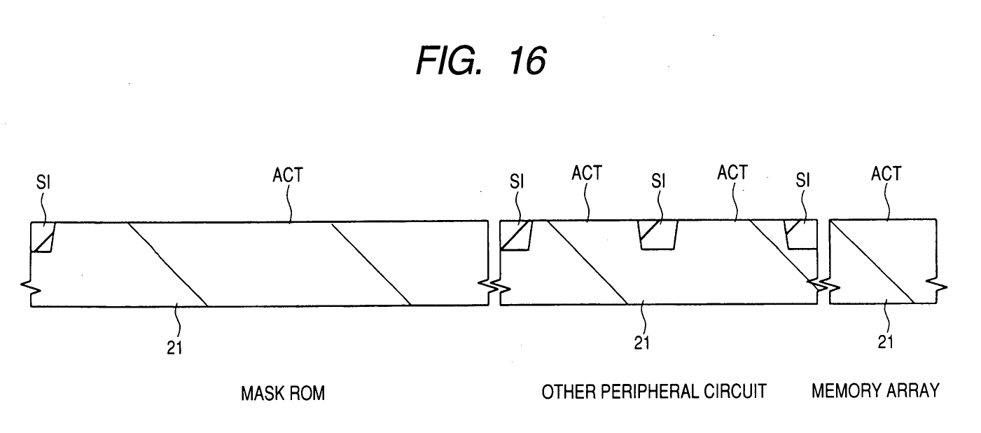

FIGS. 15 and 16 illustrate the flash memory of Embodiment 2 during its manufacturing step. FIG. 15(a) is a fragmentary plan view of a mask ROM region and FIG. 15(b) is a fragmentary plan view of the other peripheral circuit region. FIG. 16 is a fragmentary cross-sectional view including the mask ROM region, other peripheral circuit region and memory array, and in the mask ROM region, a fragmentary cross-sectional view taken along a line A-A of FIG. 15(a) is shown.

In the main surface of a semiconductor substrate 21 made of, for example, single crystal silicon, an isolation portion SI in the form of a trench and an active region ACT encompassed thereby are formed as in Embodiment 1. The isolation portion SI is formed in an element region where all the element isolation regions have a width of 0.3 μm or greater, for example, in the other peripheral circuit region, but is not formed in an element region which needs even one second element isolation region having a relatively narrow width less than 0.3 μm, for example, in the mask ROM region. In other words, the isolation portion SI is not formed in the mask ROM region which requires the second element isolation region for isolating nMIS disposed in the gate length direction. The isolation portion SI is formed in the element isolation region encompassing the whole mask ROM region.

Difference from Embodiment 1 resides in that the second element isolation region is formed between nMISs adjacent to each other in the gate width direction. In other words, in Embodiment 1, the first element isolation region (isolation portion SI) is formed between the nMISs adjacent to each other in the gate width direction in the mask ROM region. In Embodiment 2, on the other hand, the first element isolation region is not formed between the nMISs adjacent to each other in the gate width direction in the mask ROM region. The nMISs are formed in the same active region ACT and isolated by an isolation gate electrode 24 formed in the second element isolation region.

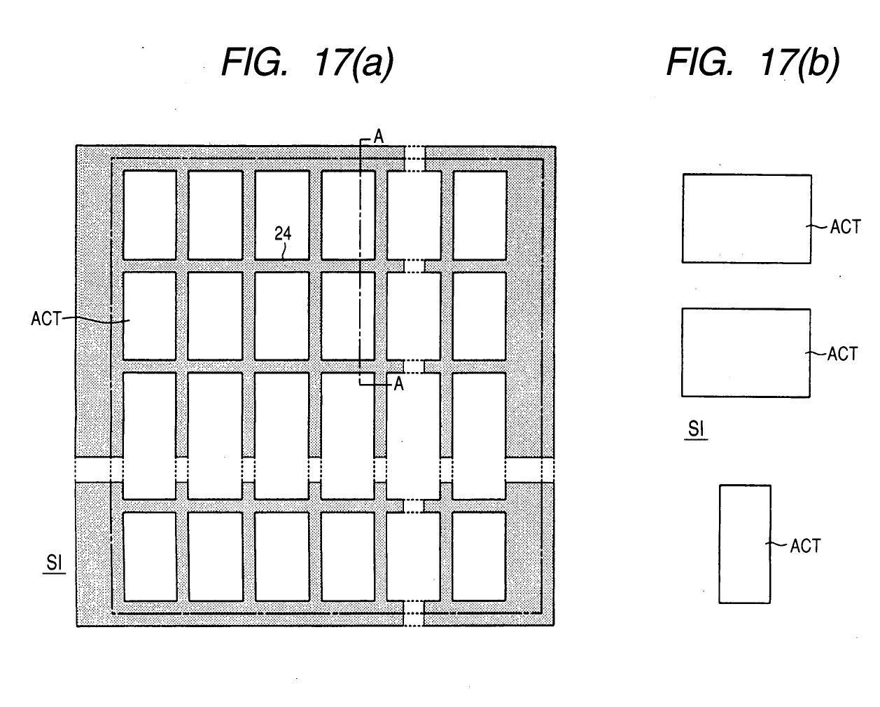

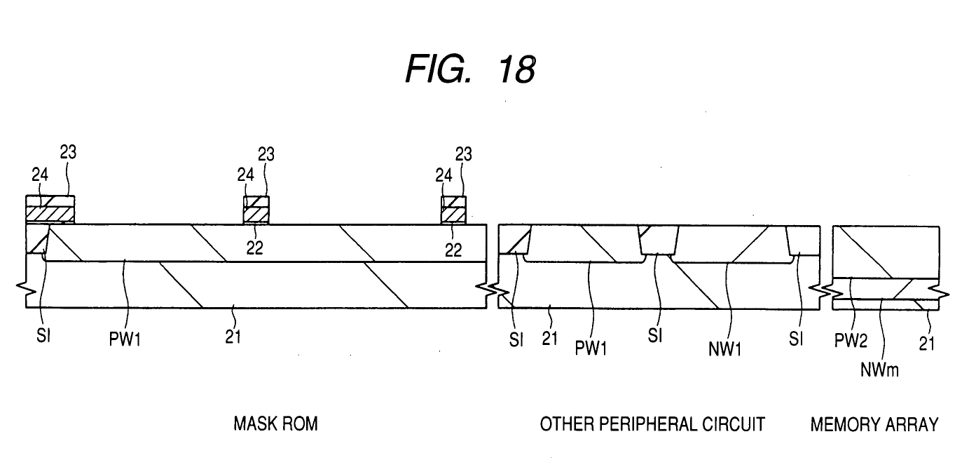

FIG. 17(a) is a fragmentary plan view of a similar portion to that of FIG. 15(a) in a manufacturing step following that of FIGS. 15 and 16; FIG. 17(b) is a fragmentary plan view of a similar portion to that of FIG. 15(b) in this manufacturing step; and FIG. 18 is a fragmentary cross-sectional view of a similar portion to that of FIG. 16 in this manufacturing step.

A buried n well NWm, p wells PW1 and PW2, and an n well NW1 are formed by introducing a predetermined impurity in a predetermined portion of the semiconductor substrate 21 at a predetermined energy by using selective ion implantation method. At this time, in addition to the ion implantation into the mask ROM region, with a resist pattern formed by photolithography as a mask, boron ions may be implanted into the p well PW1 of the second element isolation region, which has a width less than 0.3 μm and is exposed from the mask, at a dose of approximately 5×10¹² to 1×10¹³ cm⁻² as in Embodiment 1. The threshold voltage of the isolation MIS, which will be described later, can be set higher by the introduction of these impurities.

An insulating film 22 about 10 nm thick constituting a gate insulating film of the memory cell is then formed over the main surface of the semiconductor substrate 21 by thermal oxidation. During the formation of this gate insulating film, end portions of the isolation trench of the isolation portion SI are oxidized so that a stress is applied onto the interface between the silicon at end portions and the silicon oxide film. However, the first element isolation region has a width of 0.3 μm or greater and is relatively wide so that a stress occurring in the active region ACT by the isolation region SI is relatively small. A conductor film 6 about 70-nm thick made of low resistance polycrystalline silicon and a cap insulating film 23 made of silicon oxide or the like are successively deposited over the main surface of the semiconductor substrate 21 by CVD. With a resist pattern formed by photolithography as a mask, the cap insulating film 23 and conductor film exposed therefrom are removed by dry etching. By these steps, an isolation gate electrode 24 of an isolation MIS made of the conductor film is formed in the first and second element isolation regions in the mask ROM region.

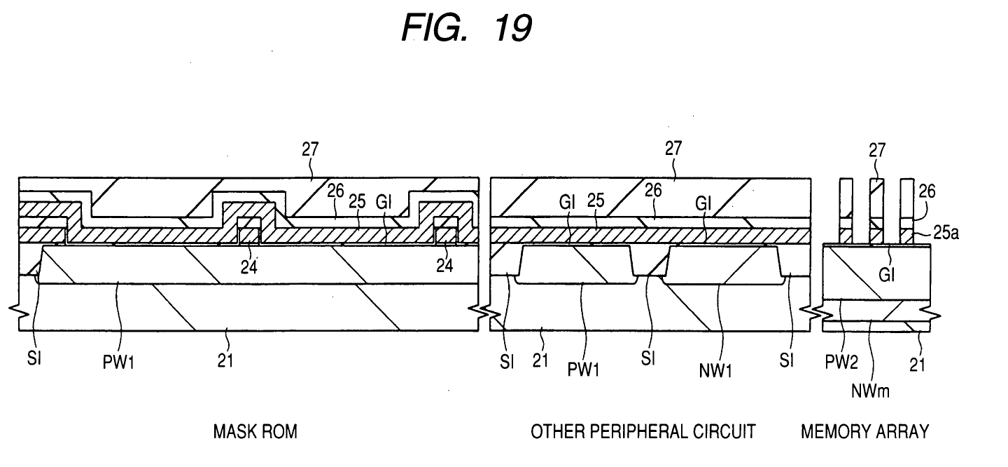

FIG. 19 is a fragmentary cross-sectional view of a similar portion to that of FIG. 16 in the manufacturing step following that of FIGS. 17 and 18.

An insulating film GI of, for example, about 10 nm thick is formed over the main surface of the semiconductor substrate 21 by thermal oxidation. The formation of the insulating film GI is accompanied with the oxidation of the end portions of the isolation trench in the isolation portion SI so that a stress is applied onto the interface between silicon at the end portions and the silicon oxide film. A stress generated in the active region ACT by the isolation portion SI is however small, because the first element isolation region has a width of 0.3 μm or greater and is relatively wide. Then, over the main surface of the semiconductor substrate 21, a conductor film 25 about 50-nm thick made of, for example, low resistance polycrystalline silicon, a silicon nitride film 26 about 70 nm thick and a silicon oxide film 27 about 250 nm thick are deposited successively from the bottom. With a resist pattern formed by photolithography as a mask, the silicon oxide film 27, silicon nitride film 26 and conductor film 25 exposed from the resist pattern are removed by dry etching, whereby a gate electrode (assist gate electrode) 25a of the memory cell made of the conductor film 25 is patterned in the gate width direction.

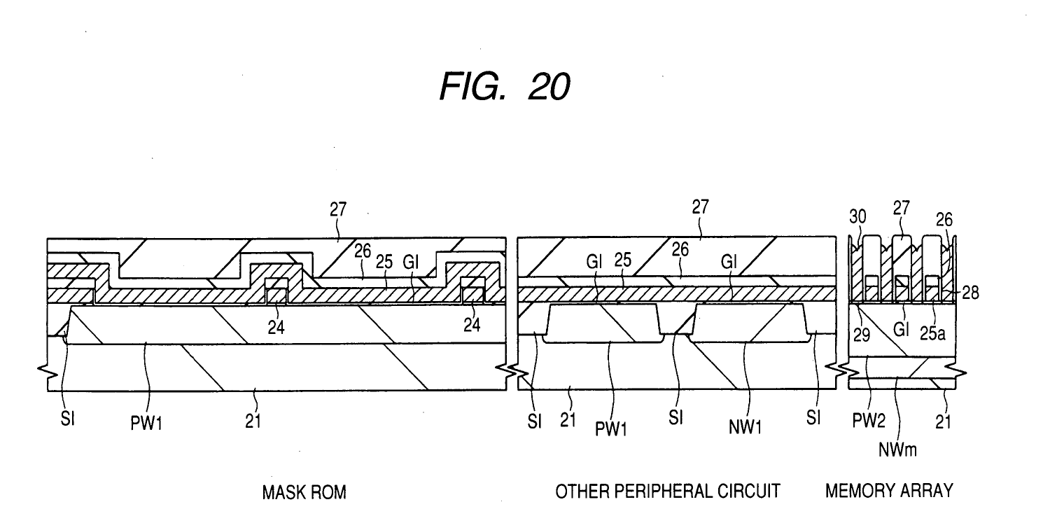

FIG. 20 is a fragmentary cross-sectional view of a similar portion to that of FIG. 16 in the manufacturing step following that of FIGT. 19.

After deposition of an insulating film made of, for example, silicon oxide over the main surface of the semiconductor substrate 21 by CVD, the insulating film is etched back by anisotropic dry etching, whereby sidewalls 28 are formed on the side surfaces of the silicon oxide film 27, silicon nitride film 26 and gate electrode 25a of the memory cell. After removal of the insulating film and the like remaining on the surface of the semiconductor substrate 21 from the memory array, an insulating film 29 about 10 nm thick constituting the gate insulating film of the memory cell is formed over the main surface of the semiconductor substrate 21, for example, by thermal oxidation.

After deposition of a conductor film about 150-nm thick made of low resistance polycrystalline silicon over the main surface of the semiconductor substrate 21 to completely fill a space between the two adjacent gate electrodes 25a, the conductor film is selectively removed from regions other than the memory array. An organic resin film is applied onto the main surface of the semiconductor substrate 21, followed by the formation, by photolithography, of a resist pattern which covers therewith the regions other than the memory array. The organic resin film exposed from the resist pattern is etched to leave it between the gate electrodes 25a adjacent to each other. With the remaining organic resin film as a mask, the conductor film exposed therefrom is etched. The organic resin film is then removed by ashing, whereby a floating gate electrode 30 of the memory cell which is a charge accumulation layer is formed in self alignment between the adjacent gate electrodes 25a adjacent to each other.

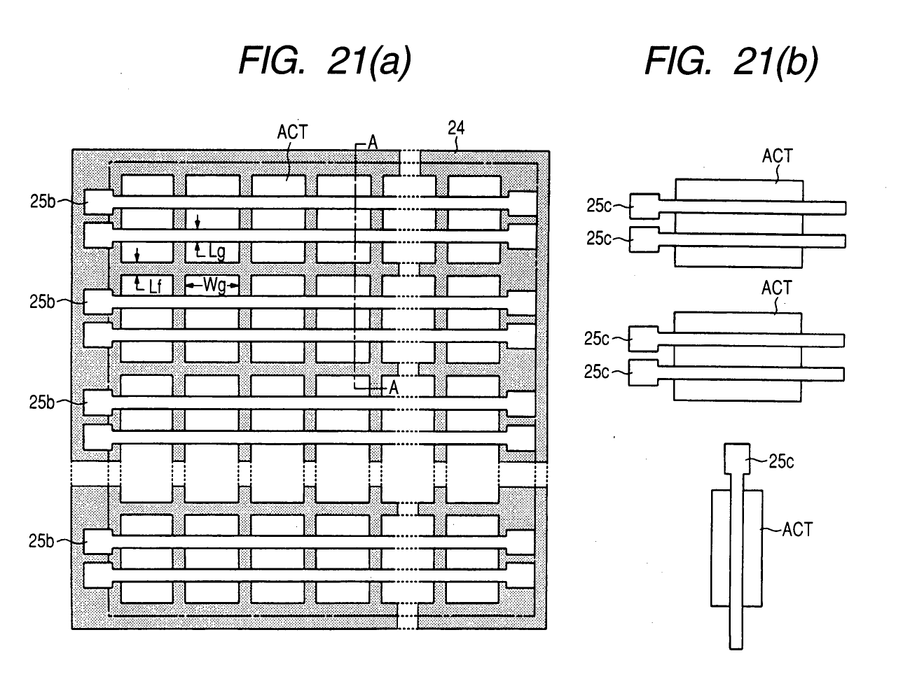

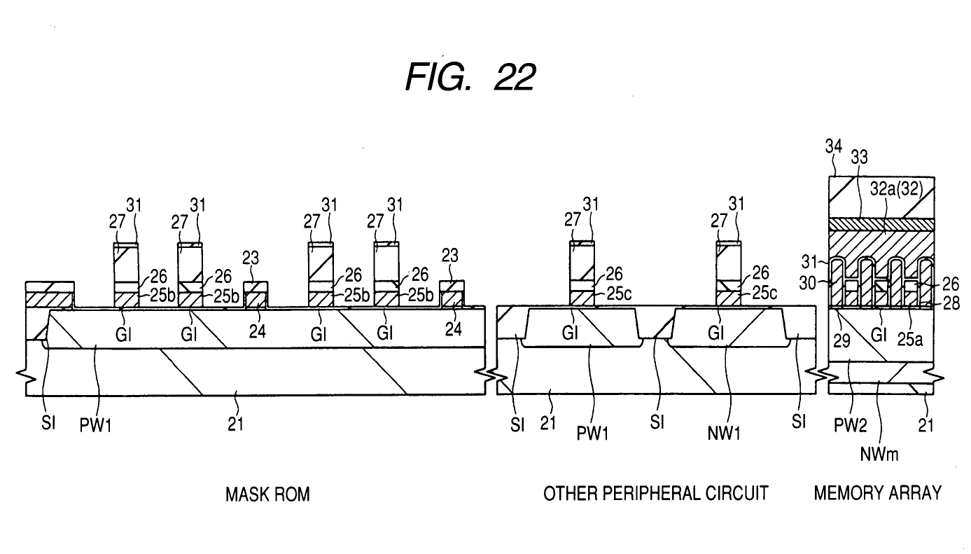

FIG. 21(a) is a fragmentary plan view of a portion similar to that of FIG. 15(a) in a manufacturing step following that of FIG. 20; FIG. 21(b) is a fragmentary plan view of a similar portion to that of FIG. 15(b) in this manufacturing step; and FIG. 22 is a fragmentary cross-sectional view of a similar portion to that of FIG. 16 in this manufacturing step.

With a resist pattern formed by photolithography as a mask, the silicon oxide film 27 is removed from the memory array while leaving the sidewalls 28 formed over the side surfaces of the gate electrode 25a.

An interlayer film 31 about 18 nm thick is then formed by successively depositing, for example, a silicon oxide film, a silicon nitride film and a silicon oxide film over the main surface of the semiconductor substrate 21 by CVD. Then, a conductor film 32 about 100 nm thick made of low resistance polycrystalline silicon, a silicide film 33 such as a tungsten silicide (WSi) film and a cap insulating film 34 made of silicon oxide are deposited successively over the main surface of the semiconductor substrate 21 by CVD.

With a resist pattern formed by photolithography as a mask, the cap insulating film 34 exposed therefrom is removed. With the remaining cap insulating film 34 as a mask, the silicide film 33 and conductor film 32 exposed therefrom are removed by dry etching, whereby a control gate electrode (word line) 32a of the memory cell is formed in the memory array. With the cap insulating film 34a and resist pattern formed by photolithography as a mask, the interlayer film 31 and conductor film exposed from the mask are removed by dry etching, whereby the floating gate electrode 30 of the memory cell is patterned in the gate length direction. By these steps, the control gate electrode 32 and the floating gate electrode 30 of the memory cell are completed.

With a photoresist pattern formed by photolithography as a mask, the interlayer film 31, silicon oxide film 27, silicon nitride film 26 and conductor film 25 exposed from the resist pattern are removed by etching from regions other than the memory array, whereby a gate electrode (local word line) 25b of the nMIS is formed in the mask ROM region and gate electrodes 25c of the nMIS and PMIS are formed in the other peripheral circuit region.

The isolation gate electrode 24 of the isolation MIS is formed in all the first and second element isolation regions in the mask ROM region. The active region ACT of the nMIS in the gate length direction and gate width direction formed in the mask ROM region can be electrically isolated from each other by this isolation gate electrode 24.

As in Embodiment 1, the nMISs adjacent to each other in the gate length direction and the gate width direction in the mask ROM region are electrically isolated by applying GND (0 V) or a negative voltage to the isolation gate electrode 24 of the isolation MIS. As a voltage applied to the isolation gate electrode 24 having a gate length less than 0.3 μm, a range of from 0 to −2 V (it is needless to say that the voltage is not limited to this range, depending on the conditions) is presumed to be appropriate. It is also possible to isolate the nMISs adjacent to each other in the gate length direction and the gate width direction in the mask ROM region by introducing an impurity into the channel region of the isolation MIS in advance and then setting the threshold voltage of the isolation MIS higher than that of the nMIS of the mask ROM region. In either case, a gate length Lf of the isolation gate electrode 24 of the isolation MIS can be made equal or less than a gate length Lg and gate width Wg of the gate electrode 25b of the nMIS in the mask ROM region and moreover, can be made shorter than 0.3 μm.

In such a manner, element isolation made of the isolation MIS can be formed in the first and second element isolation regions which isolate nMISs adjacent to each other not only in the gate length direction but also in the gate width direction in the mask ROM region. Moreover, by forming the isolation MISs in the first and second element isolation regions in the mask ROM region, a stress generated in the active region ACT in which the source and drain of the nMIS sandwiched between the first and second element isolation regions can be reduced, whereby generation of crystal defects which will otherwise occur by the stress can be prevented.

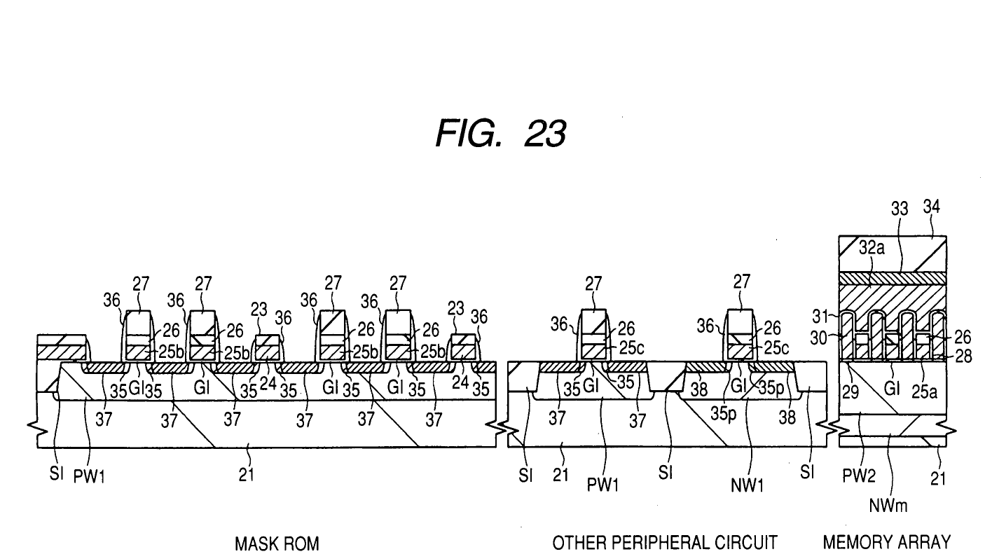

FIG. 23 is a fragmentary cross-sectional view of a similar portion to that of FIG. 16 in a manufacturing step following that of FIGS. 21 and 22.

A pair of n type semiconductor regions 35 constituting a portion of the source and drain of the nMIS in the mask ROM region and nMIS in the other peripheral circuit region and having a relatively low impurity concentration are formed. Into the n type semiconductor regions 35, for example, arsenic or phosphorous ions are implanted at a dose about from 5×10¹² to 1×10¹⁴ cm⁻². A pair of p type semiconductor regions 35p constituting a portion of the source and drain of the PMIS in the other peripheral circuit region and having a relatively low impurity concentration are then formed. Into the p type semiconductor regions 35p, for example, boron or boron fluoride ions are implanted at a dose of approximately 5×10¹² to 1×10¹⁴ cm⁻².

After deposition of an insulating film made of, for example, silicon oxide by CVD over the main surface of the semiconductor substrate 21, the insulating film is etched back by anisotropic dry etching, whereby sidewalls 36 are formed over the side surfaces of the isolation gate electrode 24, the gate electrode 25b of the nMIS in the mask ROM region, and the gate electrodes 25c of the nMIS and pMIS in the other peripheral circuit region.

A pair of n type semiconductor regions 37 constituting another portion of the source and drain of the nMIS in the mask ROM region and nMIS in the other peripheral circuit region and having a relatively high impurity concentration are formed. Into the n type semiconductor regions 37, for example, arsenic ions are introduced at a level of approximately 1×10²⁰ cm⁻³ or greater. A pair of p type semiconductor regions 38 constituting the source and drain of the PMIS in the other peripheral circuit region and having a relatively high impurity concentration are formed. Into the p type semiconductor regions 38, for example, boron ions are introduced at a level of approximately 1×10²⁰ cm⁻³ or greater.

The semiconductor substrate 1 is then heat treated at from about 900 to 1000° C. in order to activate the impurity ions thus implanted. By this heat treatment, the isolation trench of the isolation portion SI is oxidized at the end portions thereof so that a stress is applied onto the interface between silicon at the end portions and the silicon oxide film. The stress generated in the active region ACT by the isolation portion SI is however small enough to be neglected, because the first element isolation region has a width of 0.3 μm or greater and is relatively wide. By the above-described steps, the memory cell and various MISs are formed.

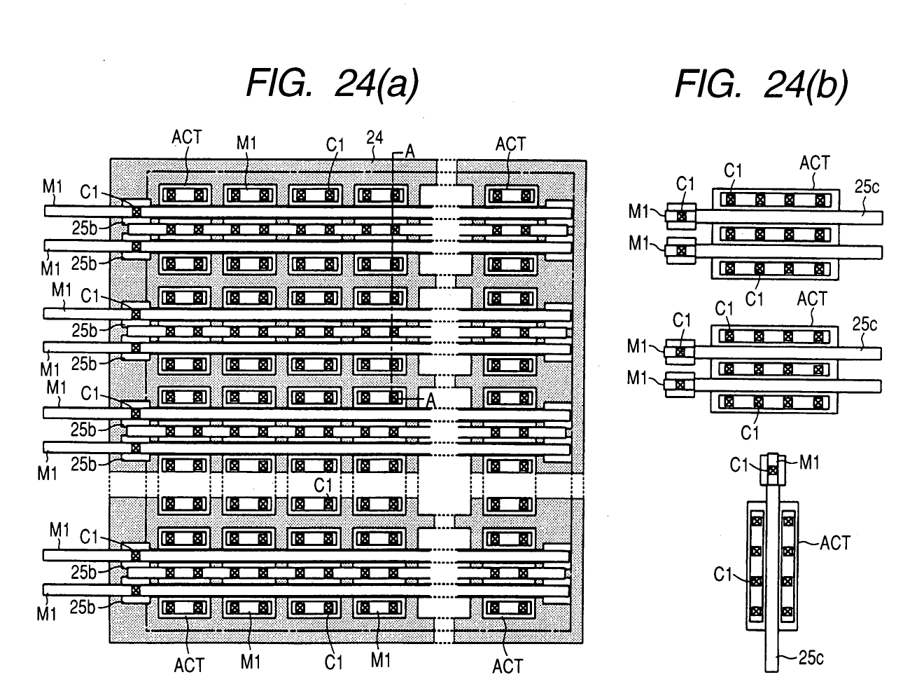

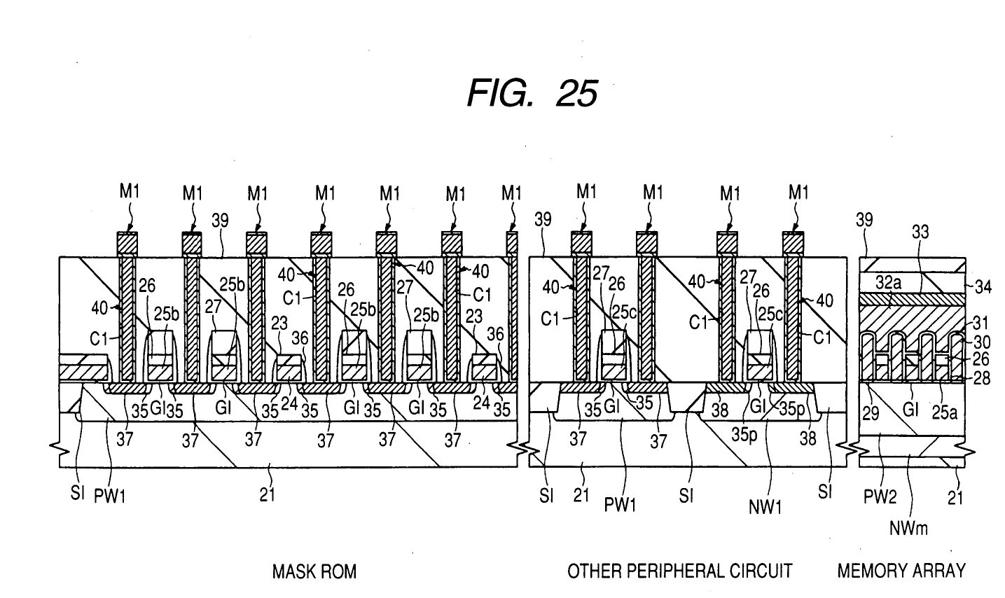

FIG. 24(a) is a fragmentary plan view of a similar portion to that of FIG. 15(a) in a manufacturing step following that of FIG. 23; FIG. 24(b) is a fragmentary plan view of a similar portion to that of FIG. 15(b) in this manufacturing step; and FIG. 25 is a fragmentary cross-sectional view of a similar portion to that of FIG. 16 in this manufacturing step.

After an insulating film 39 is formed over the main surface of the semiconductor substrate 21, contact holes C1 from which a portion of the semiconductor substrate 21 (for example, the source and drain of the various MISs) and a portion of the word line are exposed are formed in the insulating film 39. A plug 40 is formed inside of each of the contact holes C1, followed by the formation of a first-level interconnect M1.

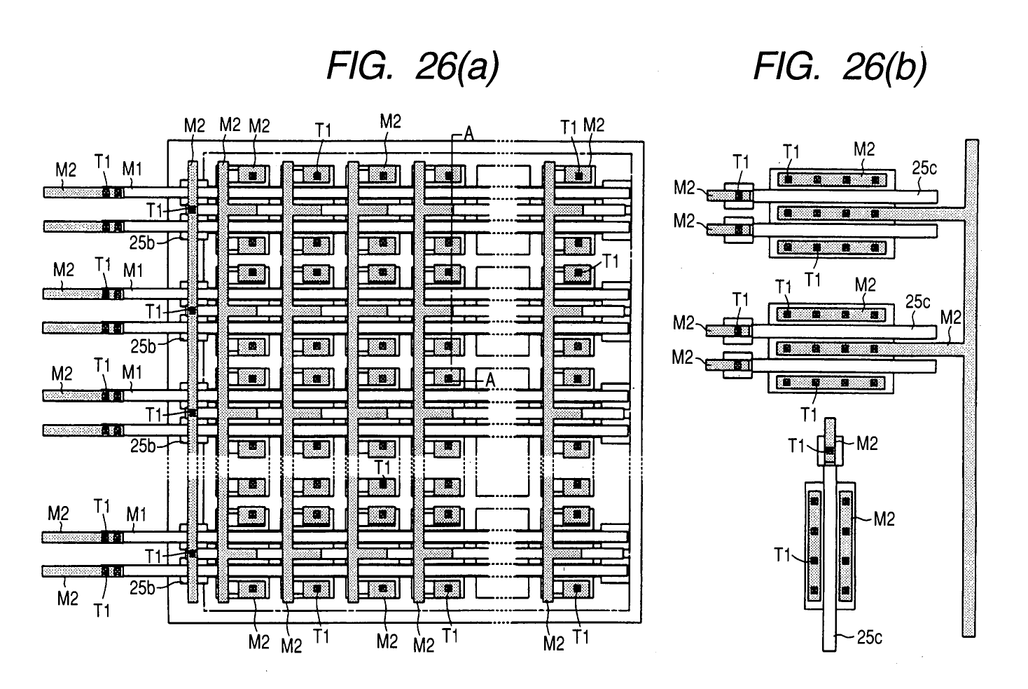

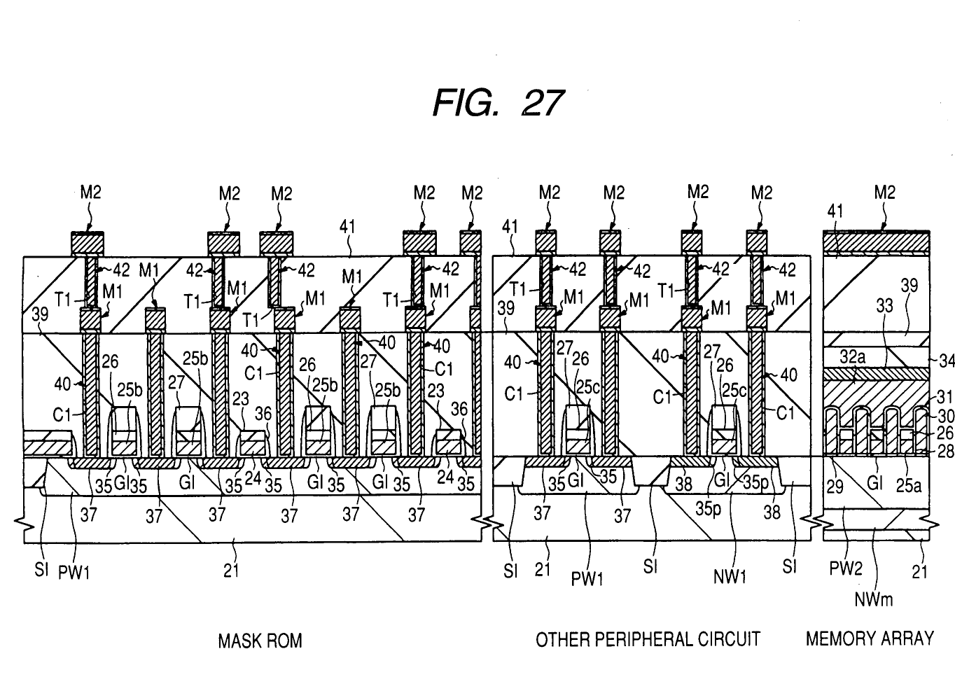

FIG. 26(a) is a fragmentary plan view of a similar portion to that of FIG. 15(a) in a manufacturing step following that of FIGS. 24 and 25; FIG. 26(b) is a fragmentary plan view of a similar portion to that of FIG. 15(b) in this manufacturing step; and FIG. 27 is a fragmentary cross-sectional view of a similar portion to that of FIG. 16 in this manufacturing step.

An insulating film 41 is deposited over the main surface of the semiconductor substrate 21. As in Embodiment 1, a through-hole T1 from which a portion of the first-level interconnect M1 is exposed is formed in the insulating film 41. A plug 42 is formed on the inside of the through-hole T1. A second-level interconnect M2 electrically connected with the first-level interconnect M1 via the plug 42 is formed. The second interconnect M2 is electrically connected to the first-level interconnect M1 via the plug 42.

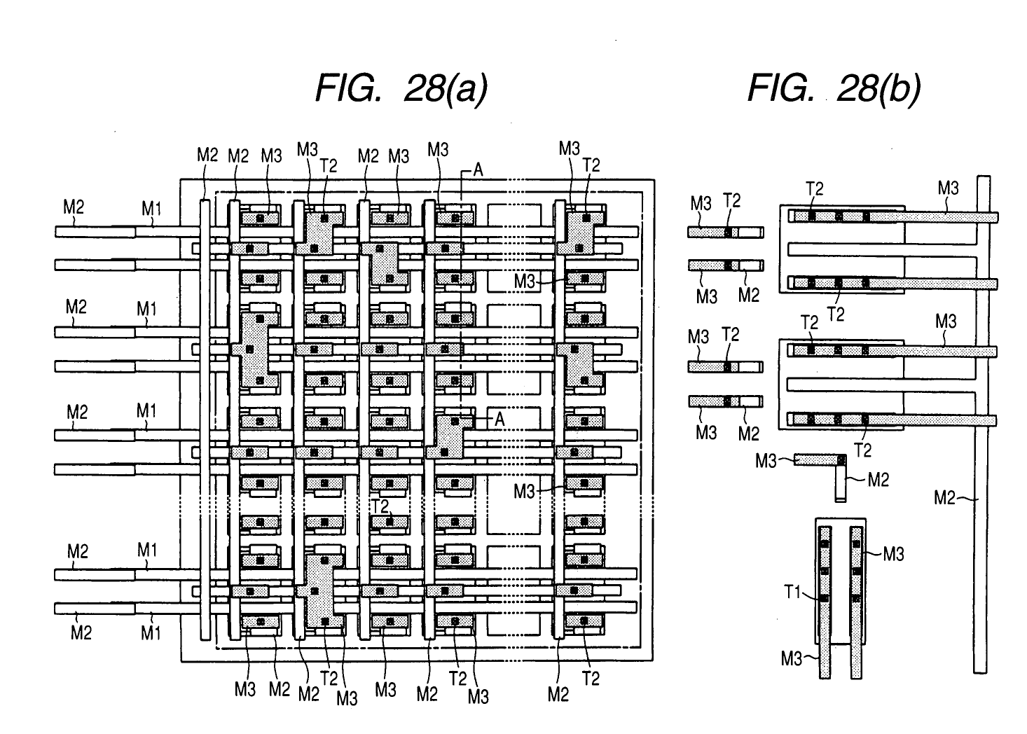

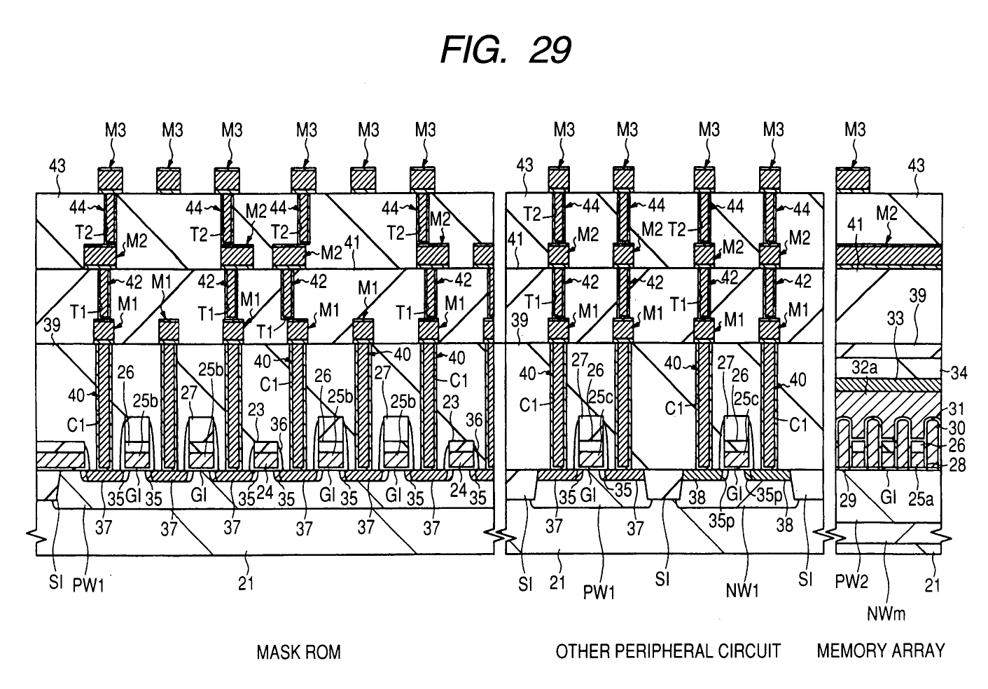

FIG. 28(a) is a fragmentary plan view of a similar portion to that of FIG. 15(a) in a manufacturing step following that of FIGS. 26 and 27; FIG. 28(b) is a fragmentary plan view of a similar portion to that of FIG. 15(b) in this manufacturing step; and FIG. 29 is a fragmentary cross-sectional view of a similar portion to that of FIG. 16 in this manufacturing step.

After deposition of an insulating film 43 over the main surface of the semiconductor substrate 21, a through-hole T2 from which the second-level interconnect M2 is exposed is formed in the insulating film 43 in a similar manner to that employed in Embodiment 1. A plug 44 is then formed on the inside of the through-hole T2 and a third-level interconnect M3 electrically connected to the second-level interconnect M2 via the plug 44 is then formed.

After upper level interconnects are formed and the uppermost interconnect is covered, at the surface thereof, with a surface protection film, an opening from which a portion of the uppermost interconnect is exposed is formed in a portion of the surface protection film to form a bonding pad. In such a manner, the flash memory is manufactured.

Embodiment 2 makes it possible to form the isolation MIS in the second element isolation region in the mask ROM region, thereby relatively decreasing a stress generated in the active region ACT sandwiched between the first element isolation regions. In other words, the nMISs in the mask ROM region are formed in one active region ACT and they are isolated by the isolation gate electrode 24 in the second element isolation region so that generation of crystal defects which will otherwise occur by the stress can be prevented. As a result, effects similar to those in Embodiment 1 are available.

### EMBODIMENT 3

In Embodiment 2, different steps are employed for the formation of the isolation gate electrode in the second element isolation region of the mask ROM region and for the formation of the assist gate electrode, the local word line of the mask ROM region and the gate electrode of the other peripheral circuit region. In Embodiment 3, on the other hand, the isolation gate electrode, and the assist gate electrode and the gate electrode of the other peripheral circuit are formed in one step.

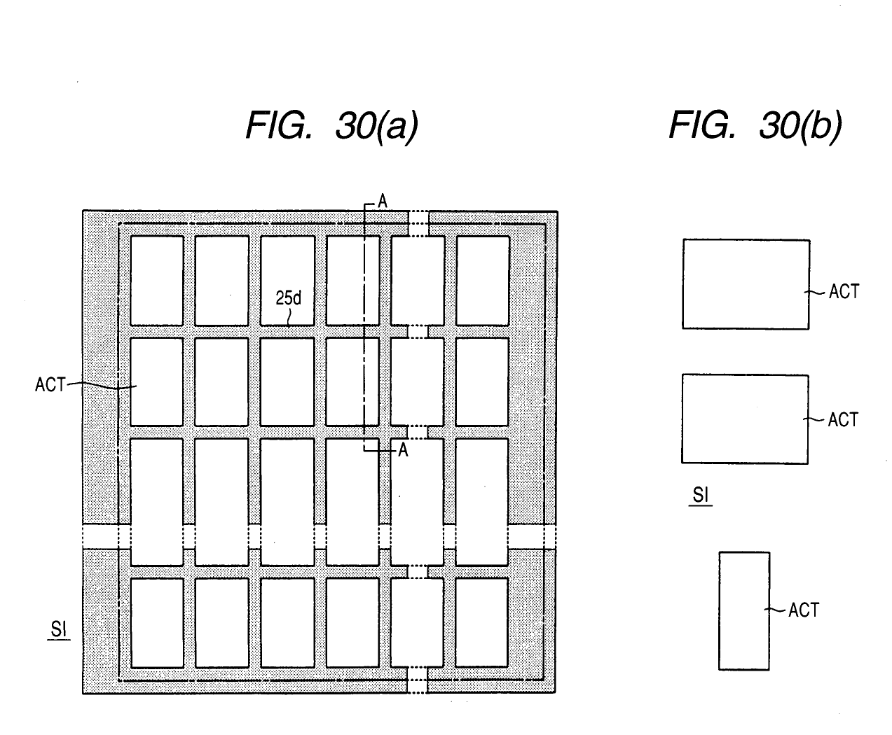

A manufacturing method of a flash memory according to Embodiment 3 will hereinafter be described in the order of steps based on FIGS. 30 to 38. Here, another application example of the present invention to a manufacturing method of an AND type flash memory having an assist gate will be described.

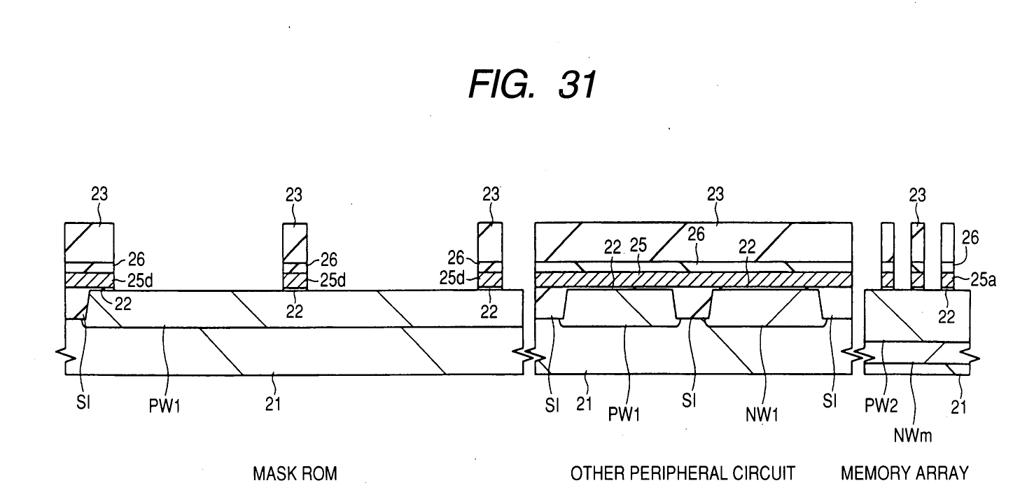

FIGS. 30(a), 30(b) and 31 illustrate the flash memory of Embodiment 3 during its manufacturing step. FIG. 30(a) is a fragmentary plan view of a mask ROM region and FIG. 30(b) is a fragmentary plan view of the other peripheral circuit region. FIG. 31 is a fragmentary cross-sectional view including the mask ROM region, other peripheral circuit region and memory array, and in the mask ROM region, a fragmentary cross-sectional view taken along a line A-A of FIG. 30(a) is shown.

In the main surface of a semiconductor substrate 21, an isolation portion SI and an active region ACT encompassed thereby are formed as in Embodiment 2. In predetermined portions of the semiconductor substrate 21, a buried n well NWm, p wells PW1 and PW2 and n well NW1 are formed.

An insulating film 22 about 10-nm thick constituting a gate insulating film of the memory cell is formed over the main surface of the semiconductor substrate 21 by thermal oxidation. The formation of the gate insulating film is accompanied by the oxidation of the end portions of the isolation trench of the isolation portion SI so that a stress is applied onto the interface between silicon at the end portions and the silicon oxide film. The stress generated in the active region ACT by the isolation portion SI is, however, relatively small, because the first element isolation region has a width of 0.3 μm or greater and is relatively wide. A polycrystalline silicon film as a low-resistant conductor film 25 about 70-nm thick, a silicon nitride film 26 and a cap insulating film 23 made of silicon oxide are deposited successively over the main surface of the semiconductor substrate 21 by CVD. With a resist pattern formed by photolithography as a mask, the cap insulating film 23, silicon nitride film 26 and conductor film 25 exposed from the mask are removed by dry etching, whereby a gate electrode (assist gate electrode) 25a is formed in the memory array and an isolation gate electrode 25d of an isolation MIS is formed in the first and second element isolation regions in the mask ROM region. These cap insulating film 23, silicon nitride film 26 and conductor film 25 are left in the other peripheral circuit region.

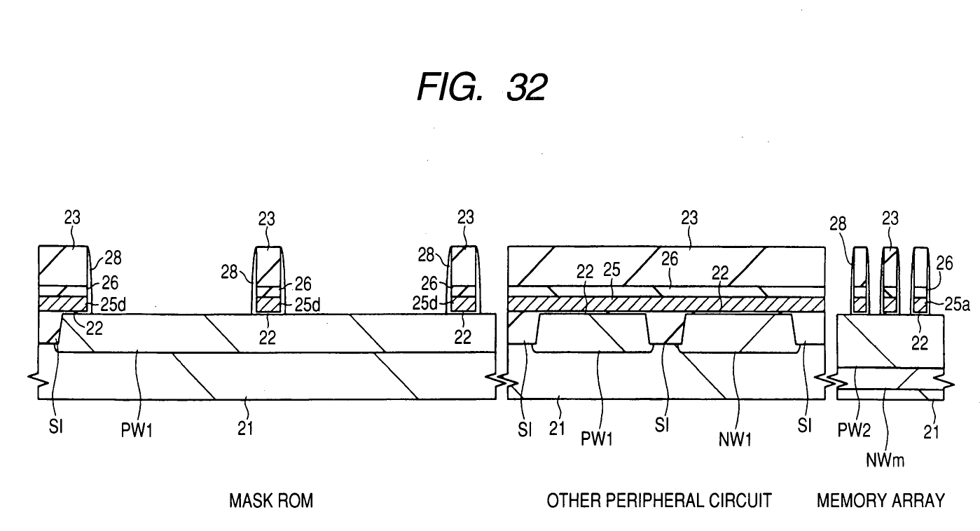

FIG. 32 is a fragmentary cross-sectional view of a similar portion to that of FIG. 31 in a manufacturing step following that of FIGS. 30 and 31.

After deposition of a silicon oxide film as an insulating film over the main surface of the semiconductor substrate 21 by CVD, the insulating film is etched back by anisotropic dry etching, whereby sidewalls 28 are formed on the side surfaces of the cap insulating film 23, silicon nitride film 26, gate electrode 25a, and the isolation gate electrode 25d.

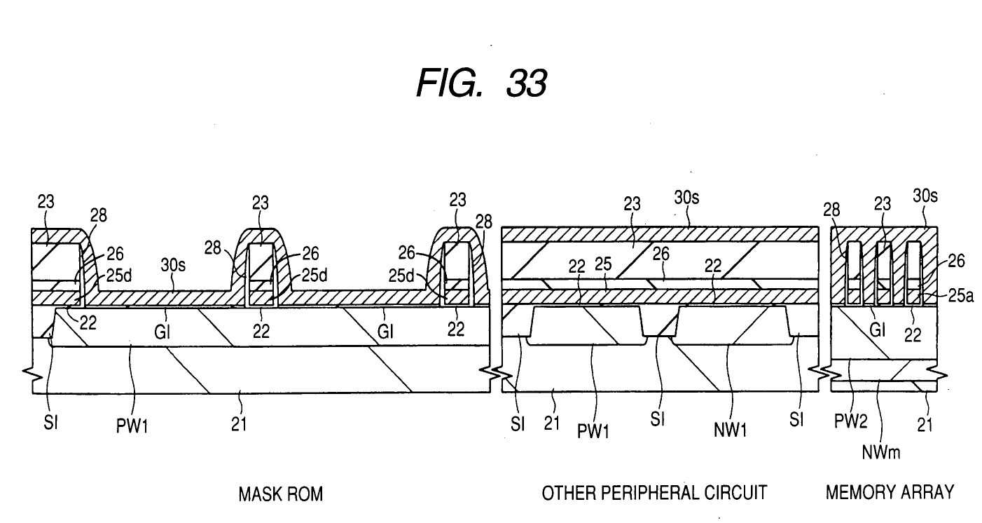

FIG. 33 is a fragmentary cross-sectional view of a similar portion to that of FIG. 31 in a manufacturing step following that of FIG. 32.

An insulating film GI, for example, about 10 nm thick, is formed over the main surface of the semiconductor substrate 21 by thermal oxidation. The formation of the insulating film GI is accompanied with the oxidation of the end portions of the isolation trench of the isolation portion SI so that a stress is applied onto the interface between silicon at the end portions and the silicon oxide film. A stress generated in the active region ACT by the isolation portion SI is however small, because the first element isolation region has a width of 0.3 μm or greater and is relatively wide. Then, over the main surface of the semiconductor substrate 21, a low-resistance polycrystalline silicon film is deposited as a conductor film 30s about 150-nm thick.

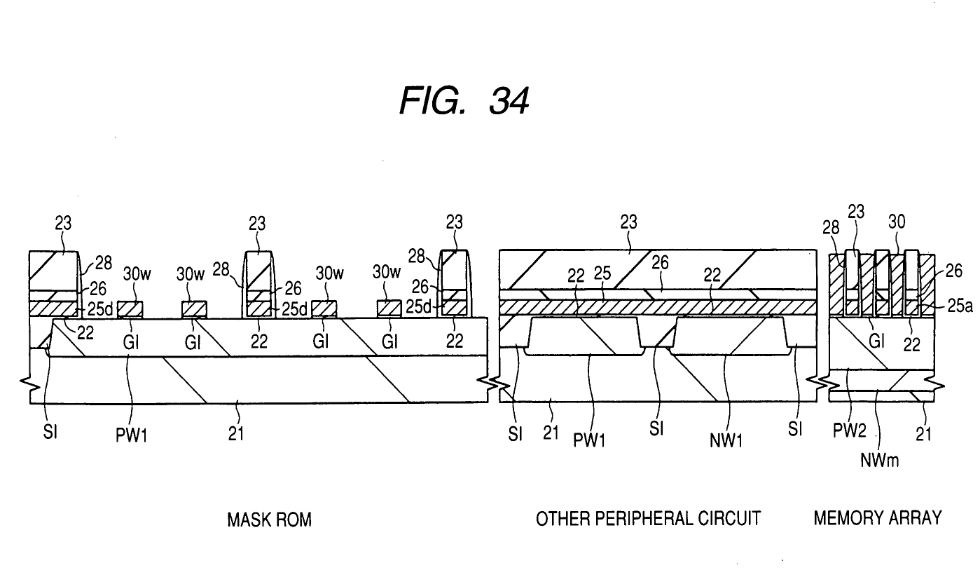

FIG. 34 is a fragmentary cross-sectional view of a similar portion to that of FIG. 31 in a manufacturing step following that of FIG. 33.

With a resist pattern formed by photolithography as a mask, the conductor film 30s is removed by dry etching, whereby gate electrodes (local word lines) 30w made of this conductor film 30s, each of the nMIS in the mask ROM region, can be obtained by patterning. The conductor film 30s of the memory array is also etched back and a columnar floating gate electrode 30 is obtained in alignment with the cap insulating film 23.

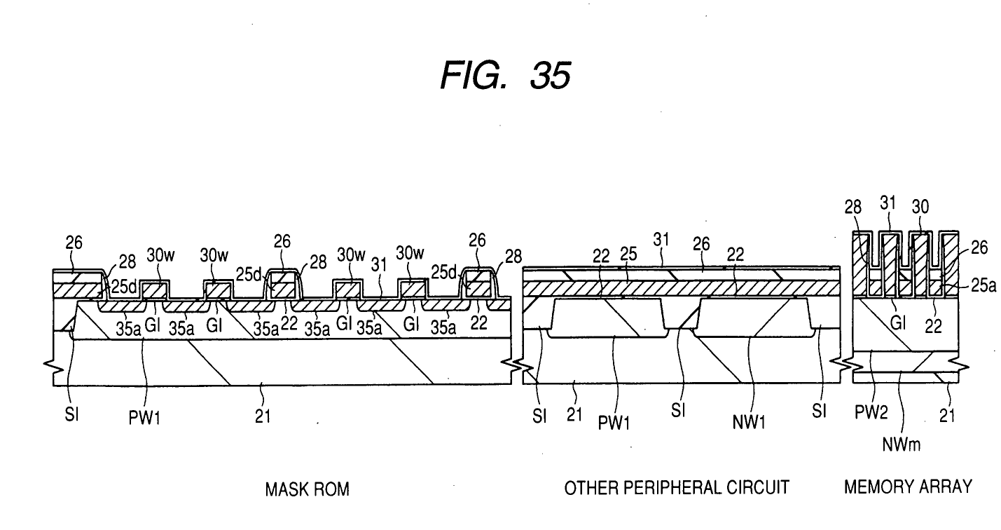

FIG. 35 is a fragmentary cross-sectional view of a similar portion to that of FIG. 31 in a manufacturing step following that of FIG. 34.

The cap insulating film 23 is etched back from the mask ROM region, other peripheral circuit region and memory array by anisotropic dry etching. A pair of n type semiconductor regions 35a constituting a portion of the source and drain of the nMIS in the mask ROM region and having a relatively low impurity concentration is then formed. At this time, the n type semiconductor regions 35a are formed in the semiconductor substrate 21 in alignment with sidewalls 25 formed over each of the gate electrode 30w of the nMIS and isolation gate electrode 25 in the mask ROM region. Into the n type semiconductor regions 35a, for example, arsenic or phosphorous ions are implanted at a dose of approximately 5×10¹² to 1×10¹⁴ cm⁻².

A silicon oxide film, a silicon nitride film and a silicon oxide film are then deposited successively over the main surface of the semiconductor substrate 21 by CVD, whereby an interlayer film 31 about 18 nm thick is formed.

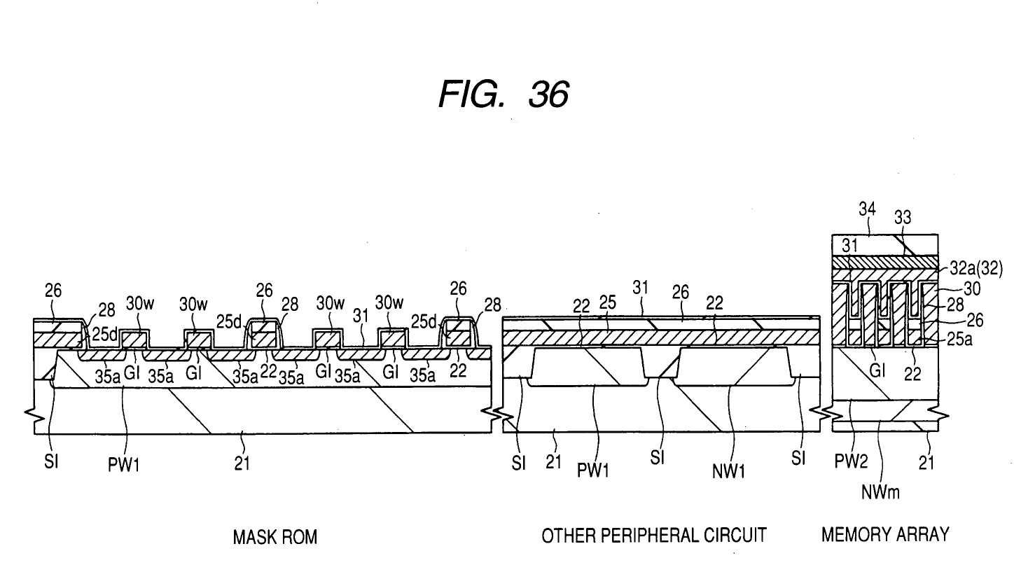

FIG. 36 is a fragmentary cross-sectional view of a similar portion to that of FIG. 31 in a manufacturing step following that of FIG. 35.

A conductor film 32 about 100 nm thick, a silicide film 33 and a cap insulating film 34 are deposited successively over the main surface of the semiconductor substrate 21 by CVD. As the conductor film 32, silicide film 33, and cap insulating film 34, a low resistance polycrystalline silicon film, tungsten silicide (WSi) film, and silicon oxide film can be used, for example, respectively. With a resist patterned formed by photolithography as a mask, the cap insulating film 34 exposed therefrom is removed. With the remaining cap insulating film 34 as a mask, the silicide film 33 and conductor film 32 exposed from the mask are removed by dry etching, whereby a control gate electrode (word line) 32a of the memory cell is formed in the memory array. The conductor film 30s exposed therefrom is etched to form a floating gate electrode 30 of the memory cell, which is a charge accumulation layer, in self alignment between two adjacent gate electrodes 25a.

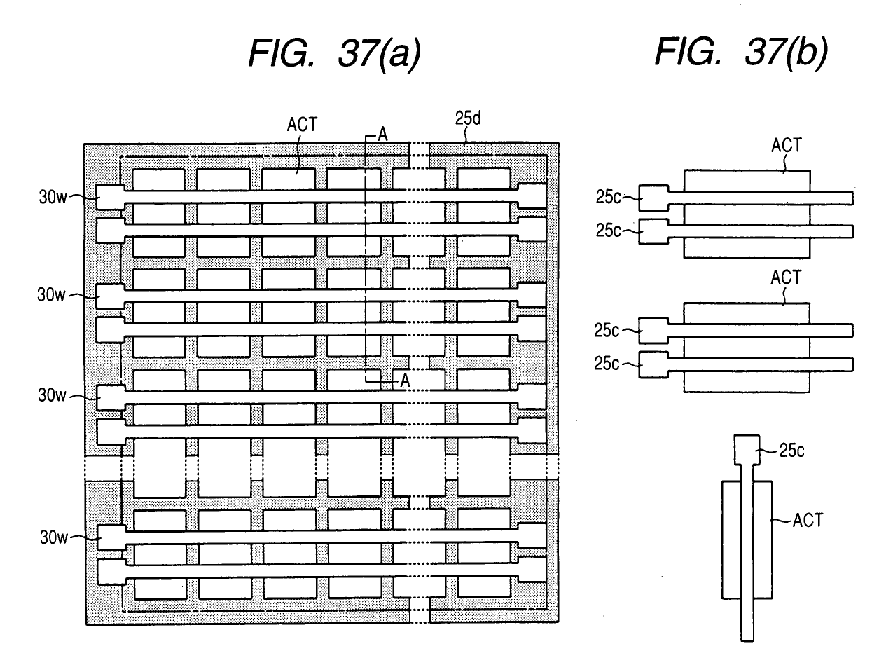

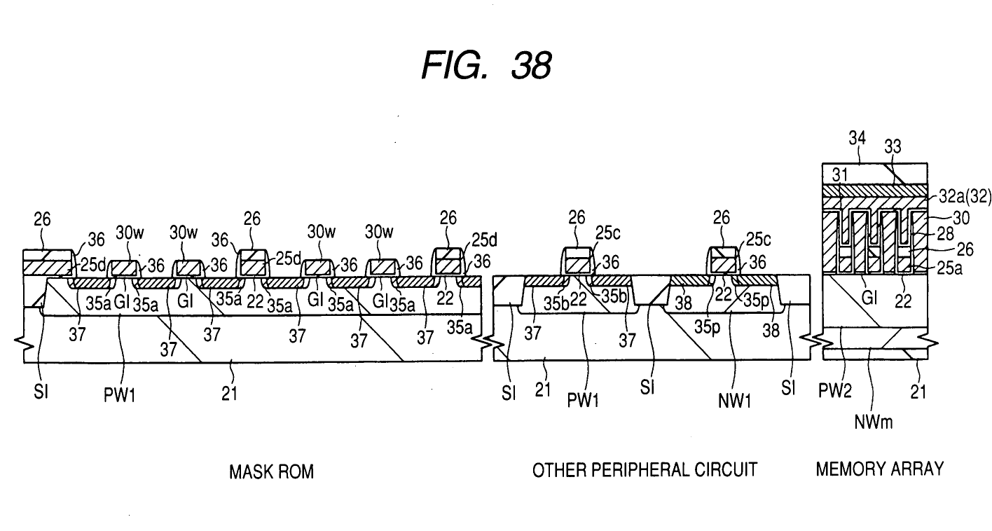

FIG. 37(a) is a fragmentary plan view of a similar portion to that of FIG. 30(a) in a manufacturing step following that of FIG. 36; FIG. 37(b) is a fragmentary plan view of a similar portion to that of FIG. 30(b) in this manufacturing step; and FIG. 38 is a fragmentary cross-sectional view of a similar portion to that of FIG. 31 in this manufacturing step.

With a resist patterned formed by photolithography as a mask, the interlayer film 31, silicon nitride film 26 and conductor film 25 exposed from the mask are removed by dry etching from regions other than the memory array, whereby gate electrodes 25c of the nMIS and pMIS are formed in the other peripheral circuit region. A pair of n type semiconductor regions 35b constituting a portion of the source and drain of the nMIS of the other peripheral circuit region and having a relatively low impurity concentration are formed. Into the n type semiconductor regions 35b, for example, arsenic or phosphorous ions are implanted at a dose of approximately 5×10¹² to 1×10¹⁴ cm ². A pair of p type semiconductor regions 35p constituting a portion of the source and drain of the pMIS of the other peripheral circuit region and having a relatively low impurity concentration are then formed. Into the p type semiconductor regions 35p, for example, boron or boron fluoride ions are implanted at a level of approximately 5×10¹² to 1×10¹⁴ cm⁻².

After deposition of an insulating film made of, for example, silicon oxide over the main surface of the semiconductor substrate 21 by CVD, the insulating film is etched back by anisotropic dry etching, whereby sidewalls 36 are formed on the side surfaces of the isolation gate electrode 25d and the gate electrode 30w of the nMIS in the mask ROM region, and the gate electrodes 25c of the nMIS and PMIS in the other peripheral circuit region.

A pair of n type semiconductor regions 37 constituting another portion of the source and drain of the nMIS in the mask ROM region and nMIS in the other peripheral circuit region and having a relatively high impurity concentration are formed. Into the n type semiconductor regions 37, for example, arsenic ions are introduced at a level of approximately 1×10²⁰ cm⁻³ or greater. A pair of p type semiconductor regions 38 constituting the source and drain of the pMIS in the other peripheral circuit region and having a relatively high impurity concentration are formed. Into the p type semiconductor regions 38, for example, boron ions are introduced at a level of approximately 1×10²⁰ cm⁻³ or greater. These n type semiconductor regions 37 and p type semiconductor regions 38 are formed in the semiconductor substrate 21 in alignment with the sidewalls 36.

The semiconductor substrate 1 is then heat treated, for example, at approximately 900 to 1,000° C. in order to activate the impurity ions thus implanted. By this heat treatment, the isolation trench of the isolated portion SI is oxidized at the end portions thereof so that a stress is applied onto the interface between silicon at the end portions and the silicon oxide film. The stress generated in the active region ACT by the isolation portion SI is however relatively small, because the first element isolation region in which the isolation portion SI has been formed has a width of 0.3 μm or greater and is relatively wide. By the above-described steps, the memory cell and various MISs are formed.

Subsequent steps are similar to those of Embodiment 2 so that description on them is omitted.

In Embodiment 3, the isolation gate electrode 25d in the mask ROM region, and the gate electrode (assist gate electrode) 25a in the memory array and the gate electrode 25c in the other peripheral circuit region are formed in the same step. The gate electrode 30w (local word line) of the nMIS in the mask ROM region and the floating gate electrode 30 of the memory cell are formed in the same step. It is possible to simplify the manufacturing steps by forming the gate electrode for element isolation and the local word line in the mask ROM as described above. In addition, similar effects to those in Embodiment 2 are available.

The inventions made by the present inventors were described specifically based on some embodiments. The present invention is however not limited to these embodiments, but it is needless to say that the invention can be modified in many ways without departing from the scope of the invention.

The inventions made by the present inventors and applied to a flash memory product having a mask ROM embedded in a peripheral circuit were so far described. They are not limited to it, but can be applied to any semiconductor device in which an element isolation region having a width less than 0.3 μm is formed.

An NOR flash memory was described in Embodiment 1, while an AND flash memory was described in Embodiments 2 and 3. The present invention can be applied to not only these flash memories but also another flash memory such as NAND flash memory as needed.

### INDUSTRIAL APPLICABILITY

The present invention is applicable, for example, to a semiconductor device equipped with a mask ROM which needs a relatively narrow element isolation region having a width less than 0.3 μm.

1. A semiconductor device comprising:
(a) a mask ROM region formed over the main surface of a semiconductor substrate and equipped with a plurality of first field effect transistors;
(b) a plurality of first active regions having the first field effect transistors formed therein, respectively; and
(c) an element isolation region for electrically isolating the first active regions adjacent to each other,
wherein the element isolation region located in a gate length direction of the first field effect transistors is constructed of a first field plate isolation.

2. A semiconductor device according to claim 1, wherein the first field plate isolation has a width not greater than the gate length of the first field effect transistors.

3. A semiconductor device according to claim 1, wherein the first field plate isolation has a width less than 0.3 μm.

4. A semiconductor device according to claim 1, wherein the element isolation region located in a gate width direction of the field effect transistors is constructed of shallow trench isolation.

5. A semiconductor device according to claim 4, wherein the shallow trench isolation has a width of 0.3 μm or greater.

6. A semiconductor device according to claim 4, wherein the width of the first field plate isolation is less than the width of the shallow trench isolation.

7. A semiconductor device according to claim 1, wherein the element isolation region located in the gate width direction of the first field effect transistors is constructed of second field plate isolation.

8. A semiconductor device according to claim 7, wherein the second field plate isolation has a width of 0.3 μm or greater.

9. A semiconductor device according to claim 7, wherein the width of the first field plate isolation is less than the width of the second field plate isolation.

10. A semiconductor device according to claim 1, wherein a gate electrode of the first field plate isolation has a potential of 0 V.

11. A semiconductor device according to claim 1, wherein a voltage of 0 V to −2 V is applied to a gate electrode of the first field effect isolation.

12. A semiconductor device according to claim 1, wherein an impurity concentration of the first active region below the first field plate isolation is set higher than an impurity concentration of the first active region below the first field effect transistor.

13. A semiconductor device according to claim 1, further comprising:
(d) a circuit region formed in a region other than the mask ROM region over the main surface of the semiconductor substrate and equipped with a plurality of second field effect transistors;
(e) a plurality of second active regions having the second field effect transistors formed therein, respectively; and
(f) an element isolation region for electrically isolating the second active regions adjacent to each other;
wherein the element isolation region for electrically isolating the second active regions adjacent to each other is constructed of the shallow trench isolation.

14. A semiconductor device according to claim 13, wherein the mask ROM region and the circuit region are formed in one semiconductor chip.

15-31. (canceled)

32. A semiconductor device comprising:
(a) a first region partitioned by an element isolation region formed over a semiconductor substrate; and
(b) a plurality of gate electrodes formed over the first region;
wherein the plurality of gate electrodes have first and second gate electrodes for first and second MISFETs and an element isolation gate electrode formed between the first and second gate electrodes for electrically isolating the first and second MISFETs.

33. A semiconductor device according to claim 32, wherein the first and second MISFETs are each an n channel MISFET.

34. A semiconductor device according to claim 33, wherein the first and second MISFETs are each an element constituting a mask ROM.

35. A semiconductor device according to claim 32, further comprising, in the first region, third and fourth MISFETs having third and fourth gate electrodes, respectively,
wherein in the gate length direction of the first MISFET, the third gate electrode, the first gate electrode, the element isolation gate electrode, the second gate electrode and the fourth gate electrode are arranged in the order of mention.

36. A semiconductor device according to claim 35, wherein the first, second, third and fourth MISFETs are each an n channel MISFET.

37. A semiconductor device according to claim 36, wherein the first, second, third and fourth MISFETs are each an element constituting a mask ROM.

38. A semiconductor device according to claim 33, wherein a voltage of from 0 V to −2 V is applied to the element isolation gate electrode during operation of the first and second MISFETs.

39. A semiconductor device according to claim 33, wherein when a positive voltage is applied to the first or second electrode, 0 V or a negative voltage is applied to the element isolation gate electrode.

40. A semiconductor device, comprising:
(a) first and second regions partitioned by an element isolation region formed by filling an insulating film in a trench of a semiconductor substrate,
(b) first and second MISFETs formed in the first region, and
(c) a third MISFET formed in the second region,
wherein the first and second MISFETs are isolated from the third MISFET by the element isolation region; and
the first MISFET is isolated from the second MISFET by a conductor film formed over the first region.

41. A semiconductor device according to claim 40, wherein the first and second MISFETs are each an n channel MISFET.

42. A semiconductor device according to claim 41, wherein the first and second MISFETs are each an element constituting a mask ROM.

43. A semiconductor device according to claim 41, wherein a voltage of from 0 V to −2V is applied to the element isolation gate electrode during operation of the first and second MISFETs.

44. A semiconductor device according to claim 41, wherein when a positive voltage is applied to the first or second gate electrode, 0 V or a negative voltage is applied to the element isolation gate electrode.
